(19) United States
(12) Patent Application Publication
(10) Pub. No.: US 2025/0126784 A1
(43) Pub. Date: Apr. 17, 2025

(54) THREE-DIMENSIONAL MEMORY DEVICE INCLUDING SLOPING WORD LINES FOR STAIRLESS CONTACT AND METHODS OF FORMING THE SAME

(71) Applicant: WESTERN DIGITAL TECHNOLOGIES, INC.,, SAN JOSE, CA (US)

(72) Inventors: Johann ALSMEIER, San Jose, CA (US); Senaka KANAKAMEDALA, San Jose, CA (US); Akira YOSHIDA, San Jose, CA (US); James KAI, Santa Clara, CA (US); Koichi MATSUNO, Fremont, CA (US); Mark D. KRAMAN, San Jose, CA (US)

(21) Appl. No.: 18/488,360

(22) Filed: Oct. 17, 2023

(51) Int. Cl. H10B 43/23; H10B 41/10; H10B 41/23; H10B 41/35; H10B 43/10; H10B 43/35

(52) U.S. Cl. CPC H10B 43/23; H10B 41/23; H10B 41/10; H10B 41/35; H10B 43/10; H10B 43/35

(57) ABSTRACT

A three-dimensional memory device includes a memory die bonded to a logic die. The memory die includes an alternating stack of insulating layers and electrically conductive layers each of which includes a horizontally-extending portion and a slanted portion that extends at a non-zero and non-orthogonal angle relative to the horizontally-extending portion, where each slanted portion has a horizontal end surface located within a first horizontal plane, memory openings vertically extending through the alternating stack, memory opening fill structures located in the memory openings, and layer contact via structures having a respective end surface that contacts a respective one of the end surfaces of the slanted portions of the electrically conductive layers within the first horizontal plane.

### FIELD

The present disclosure relates generally to the field of semiconductor devices, and particularly to a three-dimensional memory device including sloping word lines for forming stairless word line contacts and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is comprises a memory die which comprises an alternating stack of insulating layers and electrically conductive layers, wherein each of the electrically conductive layers comprise a respective horizontally-extending portion and a respective slanted portion that extends at a non-zero and non-orthogonal angle relative to the respective horizontally-extending portion, and wherein each of the slanted portions of the electrically conductive layers has a respective horizontal end surface located within a first horizontal plane; memory openings vertically extending through the alternating stack; memory opening fill structures located in the memory openings and comprising a respective vertical semiconductor channel and a respective vertical stack of memory elements located at levels of the electrically conductive layers; and layer contact via structures having a respective end surface that contacts a respective one of the end surfaces of the slanted portions of the electrically conductive layers within the first horizontal plane.

According to another aspect of the present disclosure, a method of forming a device structure is provided, which comprises: forming a recess region comprising a tapered sidewall in a matrix layer; conformally depositing an in-process alternating stack of insulating layers and sacrificial material layers, wherein the in-process alternating stack comprises a horizontally-extending portion overlying a top surface of the matrix layer and a slanted portion overlying the tapered sidewall of the recess region; forming memory openings through the horizontally-extending portion of the in-process alternating stack; forming memory opening fill structures in the memory openings, wherein each of the memory opening fill structures comprises a respective vertical semiconductor channel and a respective vertical stack of memory elements; replacing the sacrificial material layers with electrically conductive layers; forming memory-side metal interconnect structures embedded in memory-side dielectric material layers over the alternating stack of the insulating layers and the electrically conductive layers; forming memory-side bonding pads on or in the memory-side dielectric material layers; providing a logic die comprising logic-side bonding pads and a peripheral circuit; and bonding the logic-side bonding pads to the memory-side bonding pads.

### BRIEF DESCRIPTION OF THE DRAWINGS

FIG. 1 is a schematic vertical cross-sectional view of an exemplary structure after formation of a matrix layer and a patterned grayscale photoresist layer according to an embodiment of the present disclosure.

FIG. 2 is a schematic vertical cross-sectional view of the exemplary structure after formation of a recess region in the matrix layer and after formation of an etch-stop dielectric layer according to an embodiment of the present disclosure.

FIG. 3 is a schematic vertical cross-sectional view of the exemplary structure after formation of a first alternating stack of first insulating layers and first sacrificial material layers according to an embodiment of the present disclosure.

FIG. 4 is a schematic vertical cross-sectional view of the exemplary structure after formation of first-tier memory openings according to an embodiment of the present disclosure.

FIG. 5 is a schematic vertical cross-sectional view of the exemplary structure after formation of first-tier sacrificial memory opening fill structures according to an embodiment of the present disclosure.

FIG. 6 is a schematic vertical cross-sectional view of the exemplary structure after formation of a second alternating stack of second insulating layers and second sacrificial material layers according to an embodiment of the present disclosure.

FIG. 7 is a schematic vertical cross-sectional view of the exemplary structure after formation of a dielectric mesa structure according to an embodiment of the present disclosure.

FIG. 8 is a schematic vertical cross-sectional view of the exemplary structure after formation of second-tier memory openings according to an embodiment of the present disclosure.

FIG. 9 is a schematic vertical cross-sectional view of the exemplary structure after formation of inter-tier memory openings according to an embodiment of the present disclosure.

FIGS. 10A-10C are sequential vertical cross-sectional views of a region around a memory opening during formation of a memory opening fill structure according to an embodiment of the present disclosure.

FIG. 11 is a schematic vertical cross-sectional view of the exemplary structure after formation of memory opening fill structures according to an embodiment of the present disclosure.

FIG. 12 is a schematic vertical cross-sectional view of the exemplary structure after formation of a source layer according to an embodiment of the present disclosure.

FIG. 13 is a schematic vertical cross-sectional view of the exemplary structure after formation of a backside dielectric layer and a sacrificial cover layer according to an embodiment of the present disclosure.

FIG. 14 is a schematic vertical cross-sectional view of the exemplary structure after attaching a handle substrate according to an embodiment of the present disclosure.

FIG. 15 is a schematic vertical cross-sectional view of the exemplary structure after formation of lateral isolation trenches according to an embodiment of the present disclosure.

FIG. 16 is a schematic vertical cross-sectional view of the exemplary structure after formation of laterally-extending cavities according to an embodiment of the present disclosure.

FIG. 17 is a schematic vertical cross-sectional view of the exemplary structure after formation of electrically conductive layers according to an embodiment of the present disclosure.

FIG. 18 is a schematic vertical cross-sectional view of the exemplary structure after formation of a lateral isolation trench fill structure according to an embodiment of the present disclosure.

FIG. 19 is a schematic vertical cross-sectional view of the exemplary structure after removal of end portions of each memory film and each vertical semiconductor channel according to an embodiment of the present disclosure.

FIG. 20 is a schematic vertical cross-sectional view of the exemplary structure after formation of drain regions according to an embodiment of the present disclosure.

FIG. 21A is a schematic vertical cross-sectional view of the exemplary structure after formation of a contact-level dielectric layer, contact via structures, and through-mesa connection via structures according to an embodiment of the present disclosure.

FIG. 21B is a top-down view of a region of the exemplary structure of FIG. 21A.

FIG. 22A is a schematic vertical cross-sectional view of the exemplary structure after formation of a connection-level dielectric layer and connection via structures according to an embodiment of the present disclosure.

FIG. 22B is a top-down view of a region of the exemplary structure of FIG. 22A.

FIG. 23 is a vertical cross-sectional view of the exemplary structure after formation of a memory die according to an embodiment of the present disclosure.

FIG. 24 is a vertical cross-sectional view of the exemplary structure after formation of a bonded assembly of the memory die and the logic die according to an embodiment of the present disclosure.

FIG. 25 is a vertical cross-sectional view of the exemplary structure after removal of the handle substrate and formation of backside contact structures according to an embodiment of the present disclosure.

### DETAILED DESCRIPTION

As discussed above, the embodiments of the present disclosure are directed to a three-dimensional memory device including sloping word lines for forming stairless word line contacts and methods for manufacturing the same, the various aspects of which are described below. Embodiments of the disclosure can be employed to form various structures including a multilevel memory structure, non-limiting examples of which include semiconductor devices, such as three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

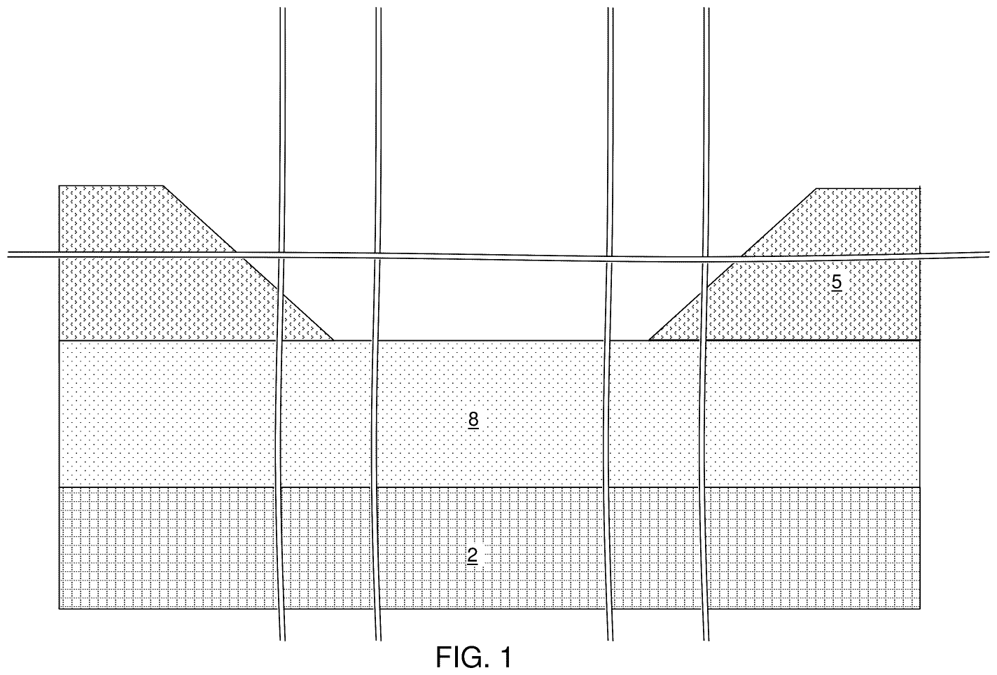

Referring to FIG. 1, an exemplary structure according to an embodiment of the present disclosure is illustrated, which comprises a carrier substrate 2. The carrier substrate 2 may comprise any substrate that is large enough to form a plurality of semiconductor dies thereupon. For example, the carrier substrate 2 may have a circular area with a diameter of 150 mm to 450 mm, or may have a rectangular shape. The carrier substrate 2 may be a semiconductor substrate (e.g., silicon wafer), an insulating substrate, a conductive substrate, or a composite substrate. The thickness of the carrier substrate 2 may be in a range from 300 microns to 1.2 mm, although lesser and greater thicknesses may also be employed.

A matrix layer 8 may be formed over the carrier substrate 2. The matrix layer 8 comprise a sacrificial material that can be employed as a matrix for an alternating stack of insulating layers and spacer material layers to be subsequently formed on the matrix layer. For example, the matrix layer 8 may comprise a dielectric material such as silicon oxide or a polymer material, or a semiconductor material, such as amorphous silicon, polysilicon, silicon-germanium, or a compound semiconductor material. The thickness of the matrix layer 8 is at least equal to a total height of an alternating stack of insulating layers and electrically conductive layers to be subsequently formed on the matrix layer 8. In an illustrative example, the thickness of the matrix layer 8 may be in a range from 1 micron to 20 microns, such as from 1.5 microns to 10 microns, although lesser and greater thicknesses may also be employed.

A resist layer 5 can be applied over the matrix layer 8, and can be lithographically patterned to form a tapered opening area having two tapered sidewalls that are laterally spaced from each other along a first horizontal direction. In one embodiment, the resist layer 5 may be a nanoimprint lithography resist layer which is patterned by nanoimprint lithography. In another embodiment, the resist layer 5 may be a grayscale photoresist layer which is patterned by grayscale photolithography. Grayscale photolithography employs a grayscale lithographic mask, which differs from binary lithographic masks in that the grayscale lithographic mask allows passage of light at varying levels of light intensity during exposure. The varying levels of light transmission during lithographic exposure allows different levels of chemical change in an exposed photosensitive material, which is referred to as a grayscale photoresist material. After exposure, a development process removes unexposed or less exposed regions of the photoresist, leaving behind a remaining photoresist material portion having a varying height. The depth or height of features in the lithographically exposed and developed photoresist material corresponds to the grayscale levels of the lithographic exposure.

In the instant case, the height of the resist layer 5 may be on the order of, may be less than or may be greater than the thickness of the matrix layer 8. The lateral dimension of each tapered sidewall of the resist layer 5 corresponds to the lateral extent of layer contact via structures to be subsequently formed on electrically conductive layers within an alternating stack of insulating layers and the electrically conductive layers. In an illustrative example, the taper angle of each tapered sidewall of the resist layer 5, as measured relative to the top surface of the substrate 2, may be in a range from at least 0.5 degrees to less than 60 degrees, such as from 6 degrees to 58 degrees, including 10 degrees to 40 degrees, although lesser and greater angles may also be employed. A pair of tapered sidewalls of the resist layer 5 may be provided such that bottom edges of the tapered sidewalls of the resist layer 5 are parallel to each other, and are perpendicular to the first horizontal direction.

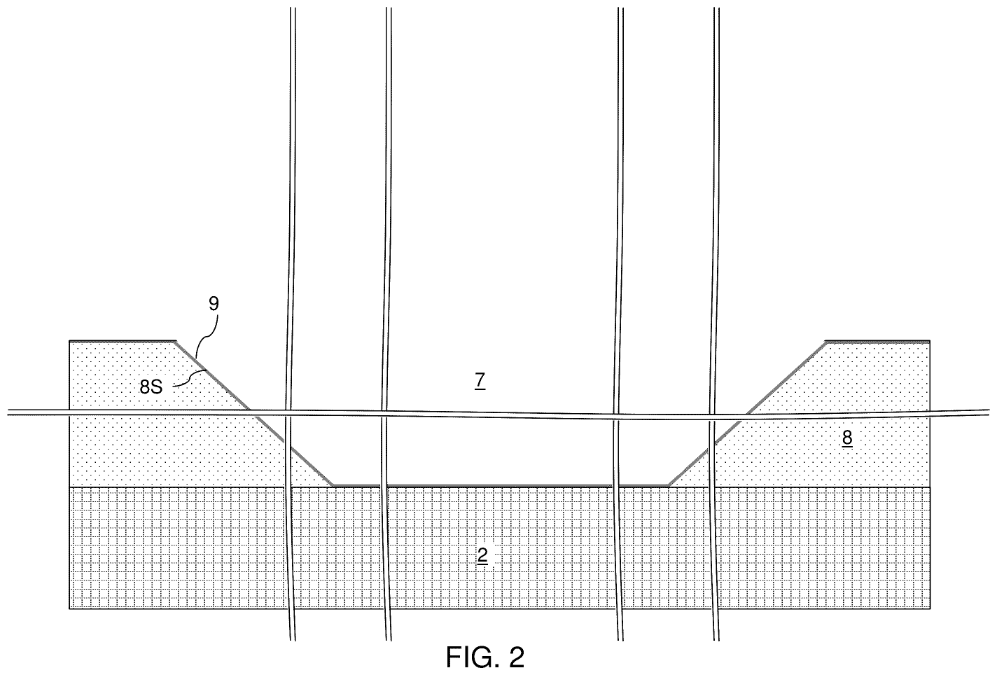

Referring to FIG. 2, an anisotropic etch process may be performed to transfer the pattern in the resist layer 5 into the matrix layer 8. A recess region 7 having a pair of tapered sidewalls 8S can be formed in the recess region 7. The taper angle of each tapered sidewall 8S of the matrix layer 8, as measured relative to the top surface of the substrate 2, may be in a range from at least 0.5 degrees to less than 60 degrees, such as from 6 degrees to 58 degrees, including 10 degrees to 40 degrees, although lesser and greater angles may also be employed. The tapered sidewalls 8S of the matrix layer 8 may be laterally spaced apart from each other along the first horizontal direction (e.g., word line direction), and may have straight bottom edges laterally extending along a second horizontal direction (e.g., bit line direction), which may be perpendicular to the first horizontal direction.

An optional etch-stop dielectric layer 9 may be optionally formed on the physically exposed surfaces of the matrix layer 8 and the carrier substrate 2. The etch-stop dielectric layer 9 may comprise a dielectric material, such as a dielectric metal oxide material such as aluminum oxide, titanium oxide, lanthanum oxide, etc. The thickness of the etch-stop dielectric layer 9 may be in a range from 10 nm to 100 nm, although lesser and greater thicknesses may also be employed.

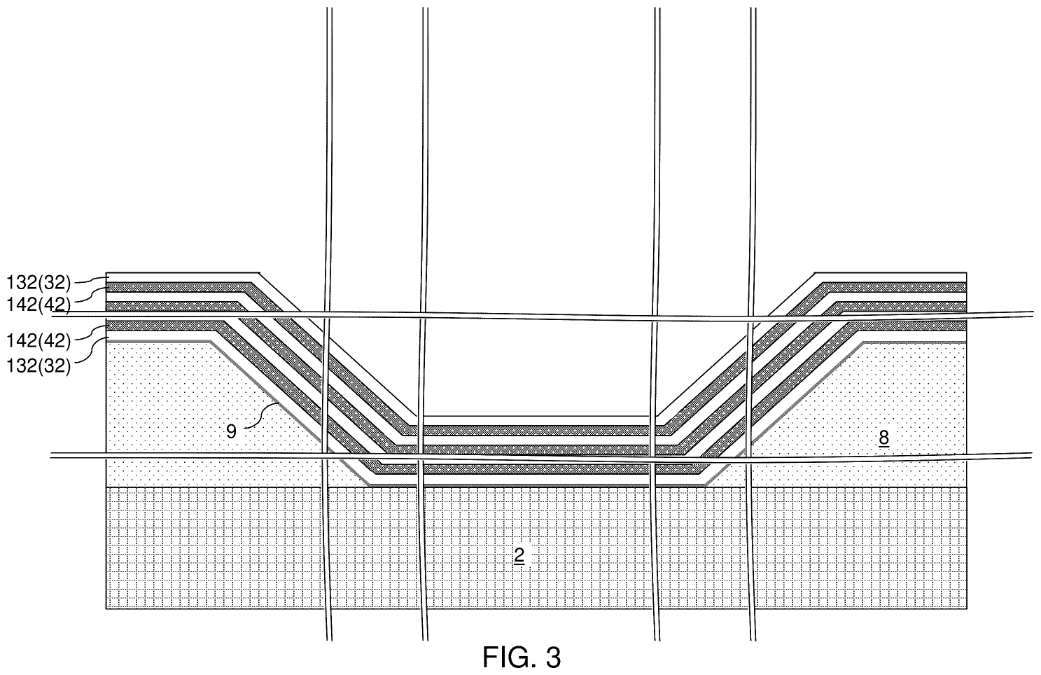

Referring to FIG. 3, a first alternating stack (132, 142) of first insulating layers 132 and first sacrificial material layers 142 can be formed over the matrix layer 8 and the carrier substrate 2. The first insulating layers 132 comprise an insulating material, such as undoped silicate glass (i.e., silicon oxide) or a doped silicate glass, and the first sacrificial material layers 142 comprise a sacrificial material, such as silicon nitride or a semiconductor material (such as amorphous silicon, polysilicon or silicon-germanium). In one embodiment, the first insulating layers 132 may comprise silicon oxide layers, and the first sacrificial material layers 142 may comprise silicon nitride layers. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed. The first insulating layers 132 comprise a first subset of insulating layers 32 to be employed in the exemplary structure, and the first sacrificial material layers 142 comprise a first subset of sacrificial material layers 42 to be employed in the exemplary structure.

Each of the first insulating layers 132 may have a thickness in a range from 10 nm to 100 nm, such as from 20 nm to 60 nm, although lesser and greater thicknesses may also be employed. Each of the first sacrificial material layers 142 may have a thickness in a range from 10 nm to 100 nm, such as from 20 nm to 60 nm, although lesser and greater thicknesses may also be employed. The first alternating stack (132, 142) extends over the top surface of the matrix layer 8, the tapered sidewalls 8S of the matrix layer 8, and the recess region 7 between the tapered sidewalls 8S of the matrix layer 8. The first alternating stack (132, 142) is a first in-process alternating stack that is subsequently modified by replacement of the first sacrificial material layers 142 with first electrically conductive layers.

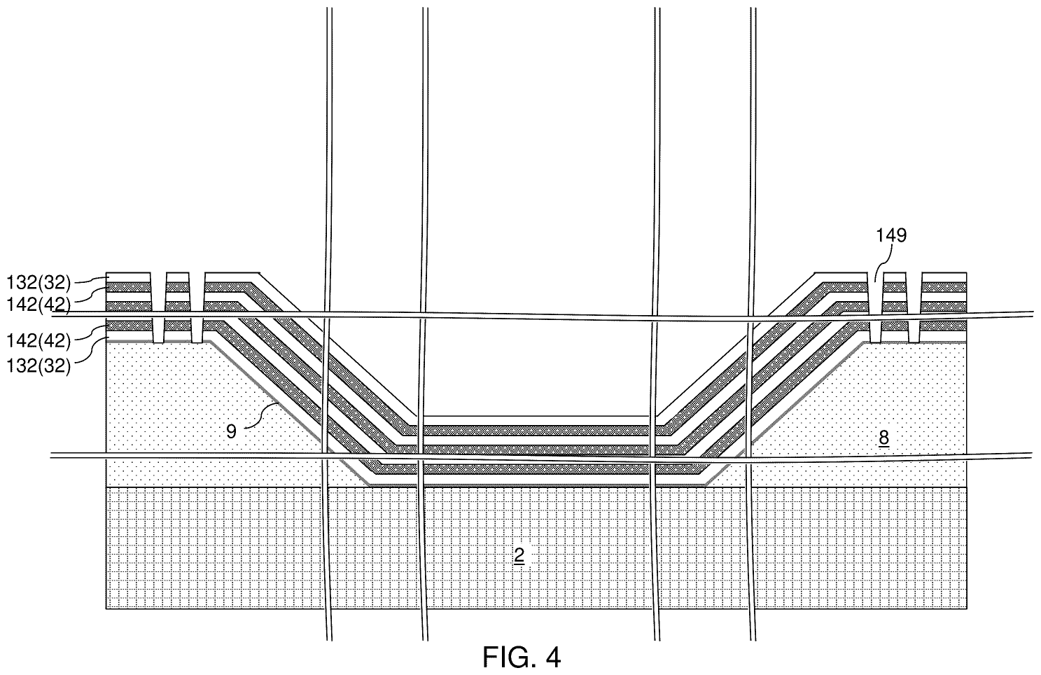

Referring to FIG. 4, a first etch mask layer (such as a patterned photoresist layer) can be formed over the first alternating stack (132, 142), and can be lithographically patterned to form discrete openings therein. A first anisotropic etch process can be performed to transfer the pattern of the discrete openings in the first etch mask layer through the first alternating stack (132, 142). First-tier memory openings 149 are formed through the portions of the first alternating stack (132, 142) that overlie the top surface of the matrix layer 8. Each of the first-tier memory openings 149 can vertically extend through the first alternating stack (132, 142) to a top surface of the etch-stop dielectric layer 9. The first etch mask layer can be subsequently removed, for example, by ashing.

The first-tier memory openings 149 may have a maximum diameter in a range from 50 nm to 400 nm, such as from 70 nm to 300 nm, although lesser and greater maximum diameters may be employed. Generally, the horizontal cross-sectional area of each first-tier memory opening 149 may increase with a vertical distance upward from the horizontal plane including the top surface of the matrix layer 8. The sidewall of each first-tier memory opening 149 may be tapered such that the lateral dimension (such as the diameter) of each first-tier memory opening 149 increases with the vertical distance upward from the horizontal plane including the top surface of the matrix layer 8. The taper angle of the sidewall of each first-tier memory opening 149, as measured relative to the vertical direction, may be in a range from 0.01 degree to 2 degrees, such as from 0.05 degree to 1 degree.

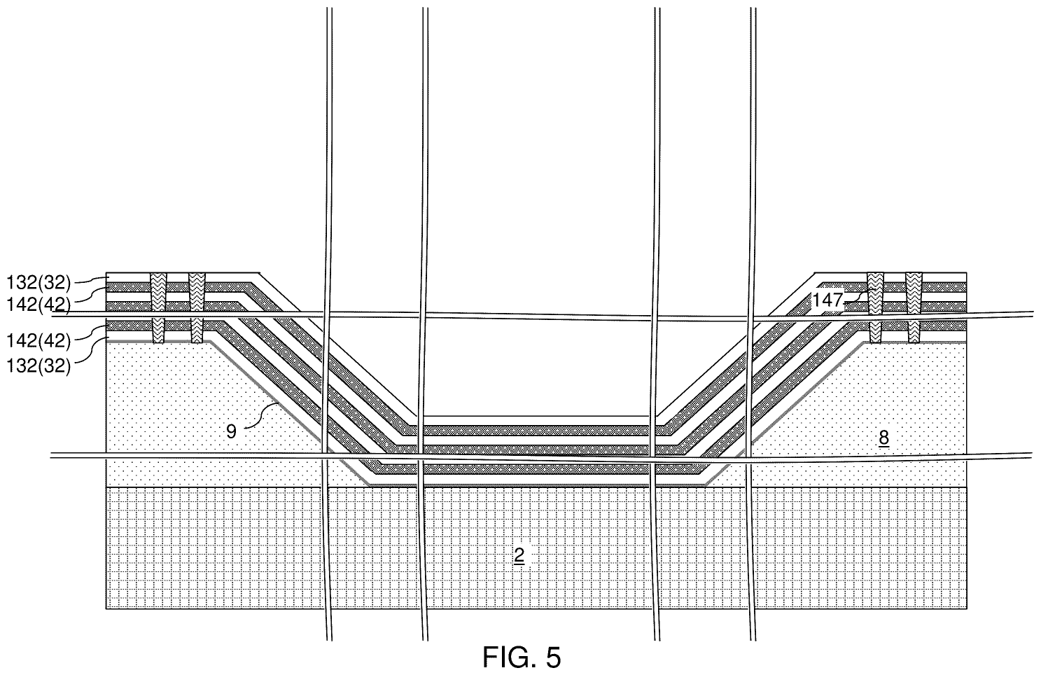

Referring to FIG. 5, an optional etch stop liner (not shown) and a first sacrificial fill material can be deposited in the first-tier memory openings 149. The optional etch stop liner (if present) comprises a thin silicon oxide layer having a thickness in a range from 1 nm to 6 nm. The first sacrificial fill material may comprise a carbon-based material (such as amorphous carbon or diamond-like carbon) or a semiconductor material (such as amorphous silicon, polysilicon or silicon-germanium). A recess etch process can be performed to remove portions of the first sacrificial fill material from above the topmost first insulating layer 132. Remaining portions of the first sacrificial fill material that fill the first-tier memory openings 149 constitute first-tier sacrificial memory opening fill structures 147. A first-tier structure is thereby formed above the matrix layer 8.

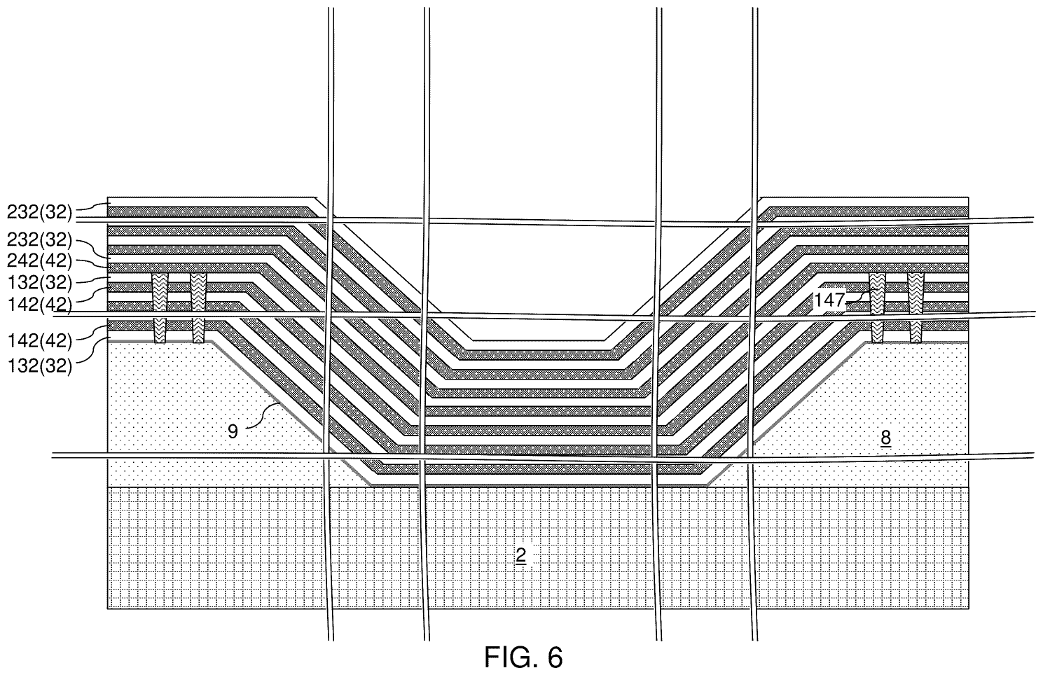

Referring to FIG. 6, an optional second alternating stack (232, 242) of second insulating layers 232 and second sacrificial material layers 242 can be formed over the first-tier structure. In one embodiment, the second insulating layers 232 may comprise the same material as the first insulating layers 132, and the second sacrificial material layers 242 may comprise the same material as the first sacrificial material layers 142. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 1,024, such as from 32 to 256, although lesser and greater number of repetitions may also be employed. The thickness of each second insulating layer 232 may be generally the same as the thickness of a first insulating layer 132, and the thickness of each second sacrificial material layer 242 may be generally the same as the thickness of a first sacrificial material layer 142. The second insulating layers 232 comprise a second subset of the insulating layers 32 to be employed in the exemplary structure, and the second sacrificial material layers 242 comprise a second subset of the sacrificial material layers 42 to be employed in the exemplary structure. The second alternating stack (232, 242) (if present) is a second in-process alternating stack that is subsequently modified by replacement of the second sacrificial material layers 242 with second electrically conductive layers.

In summary, at least one in-process alternating stack (32, 42) of insulating layers 32 and sacrificial material layers 42 can be formed over the matrix layer 8 by performing conformal deposition processes. The in-process alternating stack (32, 42) comprises a horizontally-extending portion overlying a top surface of the matrix layer 8 and a slanted portion overlying the tapered sidewall 8S of the recess region 7. Generally, each layer within the in-process alternating stack (32, 42) may comprise a respective horizontally-extending portion overlying the top surface of the matrix layer 8 and a respective slanted portion overlying the tapered sidewall 8S of the recess region 7.

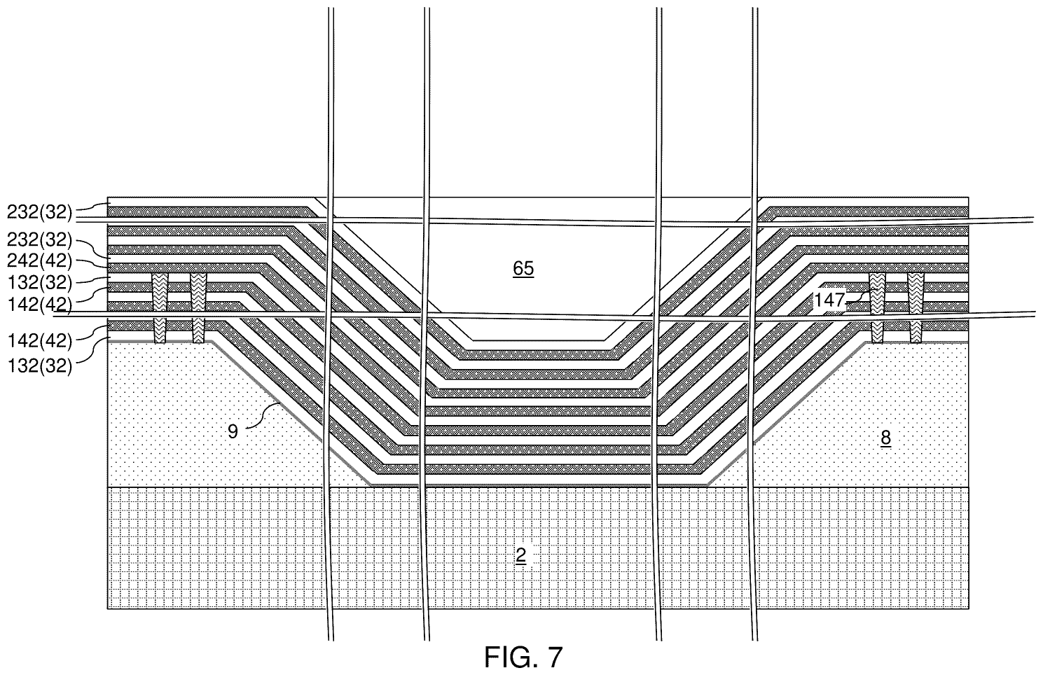

Referring to FIG. 7, a dielectric fill material can be deposited in the remaining part of the recess region 7 that underlies a horizontal plane including the topmost surface of the in-process alternating stack (32, 42). The dielectric fill material may comprise, for example, undoped silicate glass, a doped silicate glass, or a flowable oxide material. Excess portions of the dielectric fill material can be removed from above the horizontal plane including the topmost surface of the in-process alternating stack (32, 42) by performing a planarization process such as a chemical mechanical polishing (CMP) process. The remaining portion of the dielectric fill material constitutes a dielectric material portion, which is herein referred to as a dielectric mesa structure 65. The dielectric mesa structure 65 has a configuration of a mesa in an inverted view. The dielectric mesa structure 65 may have a vertical cross-sectional view of an inverted trapezoid along a vertical plane that extends in the first horizontal direction. The dielectric mesa structure 65 may have a pair of slanted sidewalls, each contacting a top surface of a respective slanted portion of a topmost insulating layer 32 within the in-process alternating stack (32, 42).

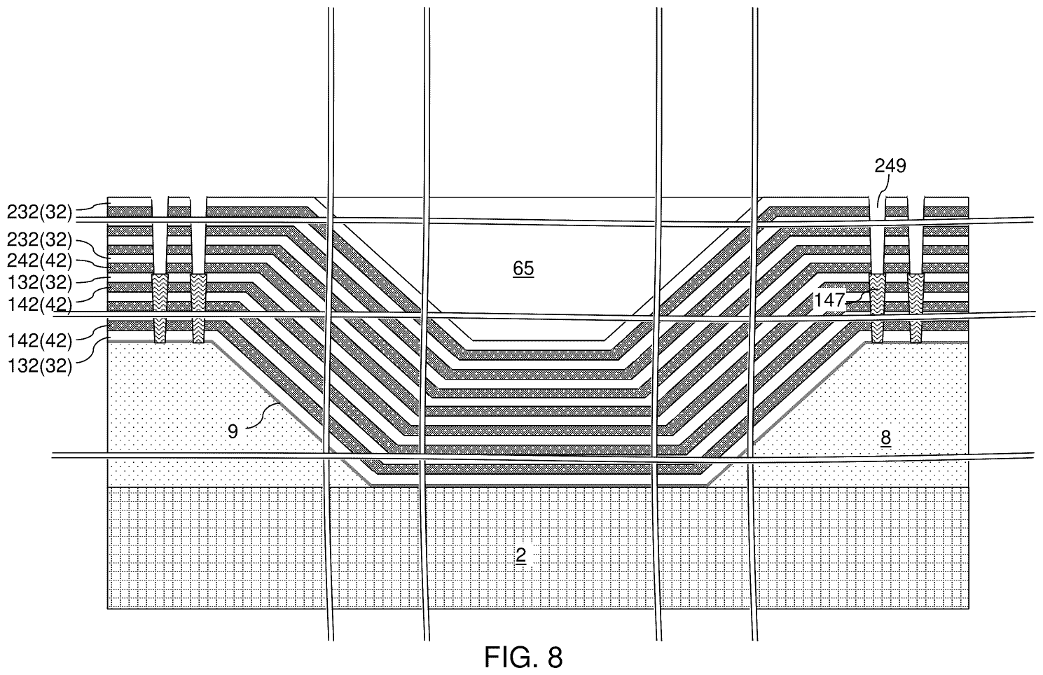

Referring to FIG. 8, a second etch mask layer (such as a patterned photoresist layer) can be formed over the second alternating stack (232, 242), and can be lithographically patterned to form discrete openings therein. A second anisotropic etch process can be performed to transfer the pattern of the discrete openings in the second etch mask layer through the second alternating stack (232, 242). Second-tier memory openings 249 are formed through the portions of the second alternating stack (232, 242) that overlie the top surface of the matrix layer 8. Each of the second-tier memory openings 249 can vertically extend through the second alternating stack (232, 242) to a top surface of a respective underlying first-tier sacrificial memory opening fill structure 147. The second etch mask layer can be subsequently removed, for example, by ashing.

The second-tier memory openings 249 may have a maximum diameter on par with the maximum diameter of the first-tier sacrificial memory opening fill structures 147. Generally, the horizontal cross-sectional area of each second-tier memory opening 249 may increase with a vertical distance upward from the horizontal plane including the top surface of the matrix layer 8. The sidewall of each second-tier memory opening 249 may be tapered such that the lateral dimension (such as the diameter) of each second-tier memory opening 249 increases with the vertical distance upward from the horizontal plane including the top surface of the matrix layer 8. The taper angle of the sidewall of each second-tier memory opening 249, as measured relative to the vertical direction, may be in a range from 0.01 degree to 2 degrees, such as from 0.05 degree to 1 degree.

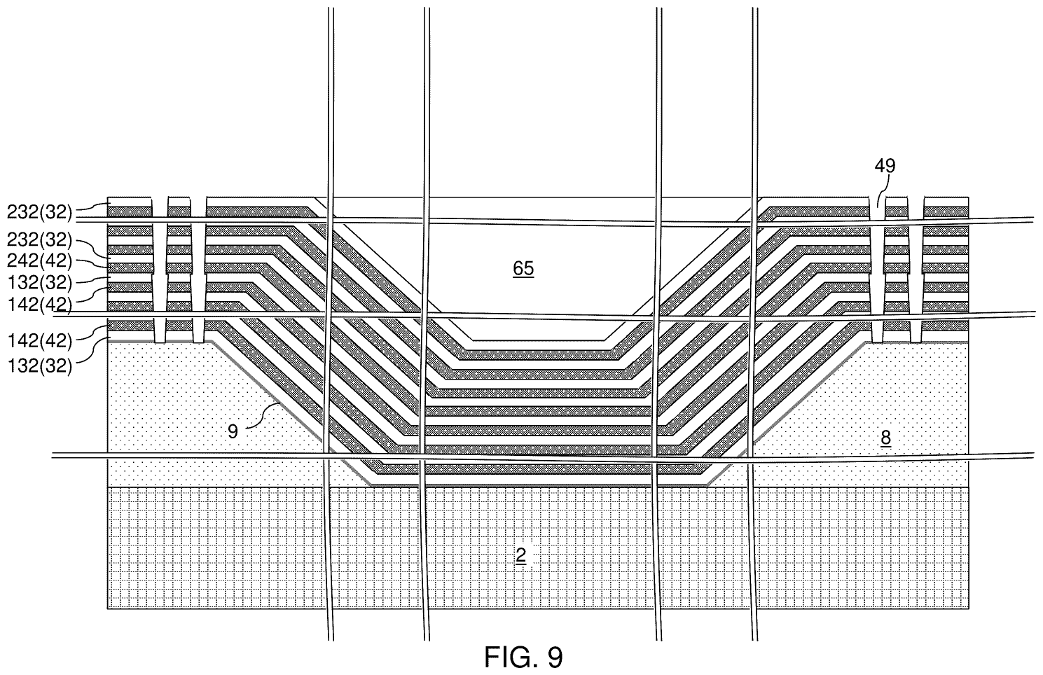

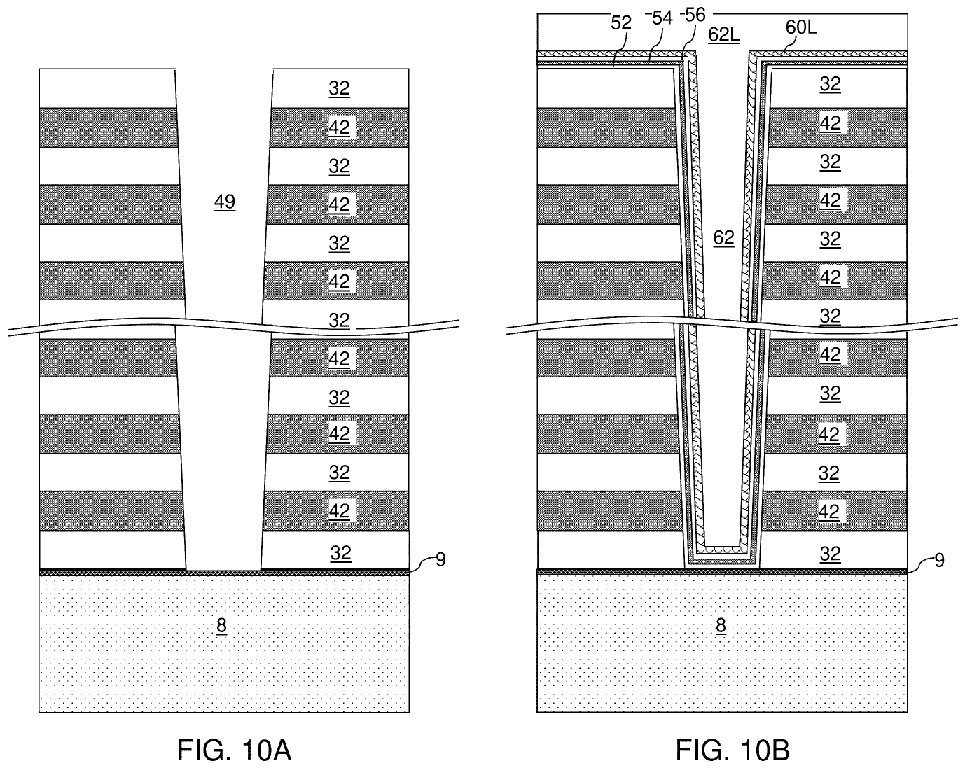

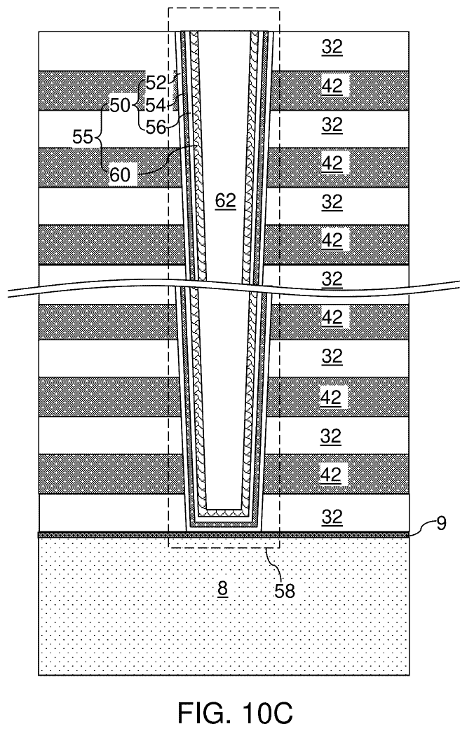

Referring to FIGS. 9 and 10A, the first-tier sacrificial memory opening fill structures 147 can be removed from underneath the second-tier memory openings 249. In one embodiment, a selective removal process can be performed, which removes the sacrificial fill material of the first-tier sacrificial memory opening fill structures 147 selective to the materials of the in-process alternating stack (32, 42) and the etch-stop dielectric layer 9. For example, if the first-tier sacrificial memory opening fill structures 147 comprise a carbon-based material, an ashing process can be performed to remove the first-tier sacrificial memory opening fill structures 147. Memory openings 49, which are also referred to inter-tier memory openings 49, can be formed through the in-process alternating stack (32, 42). Generally, each of the memory openings 49 may comprise at least one tapered sidewall that defines a respective variable width portion having a variable width that increases with a vertical distance from the horizontal plane including the top surface of the matrix layer 8.

If the memory openings 49 are formed using a single anisotropic etch process, each memory opening 49 may have a single tapered sidewall that extends from a bottommost layer to a topmost layer within the in-process alternating stack (32, 42). If the memory openings 49 are formed employing a plurality of anisotropic etch process, the number of tapered sidewalls (as counted along a vertical direction) in each memory opening 49 may be the same as the number of anisotropic etch processes employed to form the memory openings 49. In this case, the tapered sidewalls of a memory opening 49 may be interconnected through at least one annular horizontal surface of the memory opening 49 that are formed at interfaces between neighboring tier structures.

Referring to FIG. 10B, a layer stack including a memory material layer 54 can be conformally deposited in each memory opening 49. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material (e.g., silicon oxide) can be deposited in remaining volumes of the memory openings 49 and over the alternating stack (32, 42).

Referring to FIG. 10C, portions of the dielectric core layer 62L, the semiconductor channel material layer 60L, and the layer stack (52, 54, 56) that overlie the horizontal plane including the topmost surface of the topmost insulating layer within the in-process alternating stack (32, 42) can be removed by performing a planarization process, such as a chemical mechanical polishing process. Each continuous set of remaining portions of the layer stack (52, 54, 56) constitutes a memory film 50. The memory film 50 may comprise, for example, a layer stack of an optional blocking dielectric layer 52, the memory material layer 54, and an optional dielectric liner (e.g., tunneling dielectric layer) 56. Portions of each memory material layer 54 located at the levels of the sacrificial material layers 42 constitute a vertical stack of memory elements. Each remaining portion of the semiconductor channel material layer 60L in a respective memory opening 49 constitutes a vertical semiconductor channel 60. A contiguous combination of a memory film 50 and a vertical semiconductor channel 60 constitutes a memory stack structure 55. Each remaining portion of the dielectric core layer 62L constitutes a dielectric core 62. The set of all material portions within a memory opening 49 constitutes a memory opening fill structure 58.

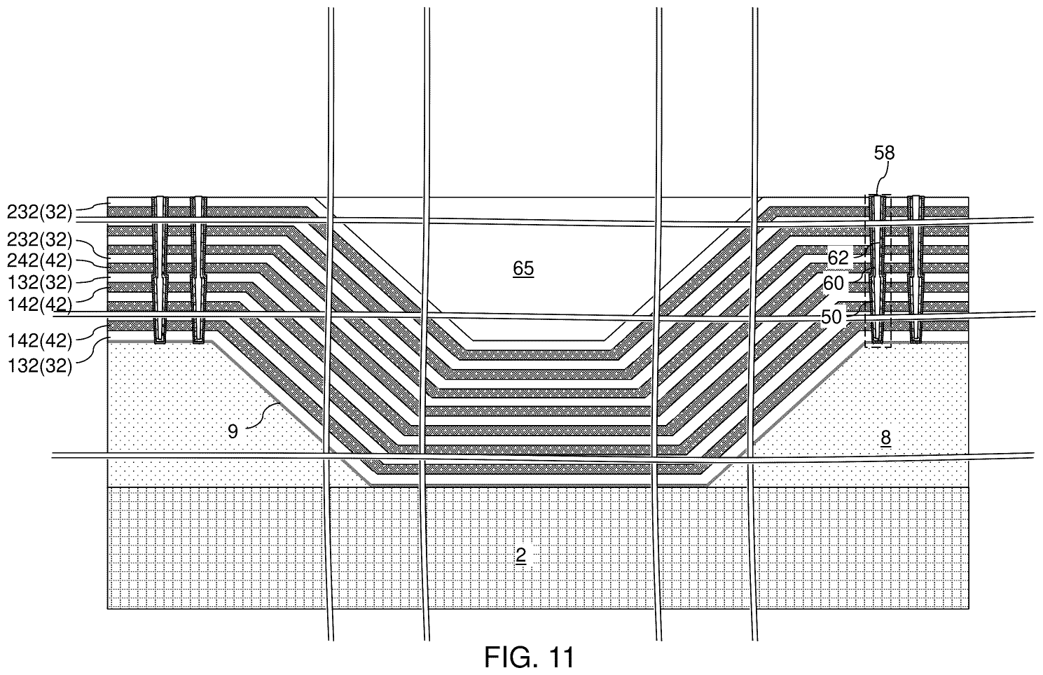

Referring to FIG. 11, the exemplary structure is illustrated after formation of the memory opening fill structures 58. Each of the memory opening fill structures 58 comprises a respective vertical stack of memory elements, and a vertical semiconductor channel 60 having a doping of a first conductivity type. In one embodiment, each of the memory opening fill structures 58 comprises at least one tapered region having a variable lateral extent that increases along an upward vertical direction when the exemplary structure is oriented as illustrated in FIG. 11.

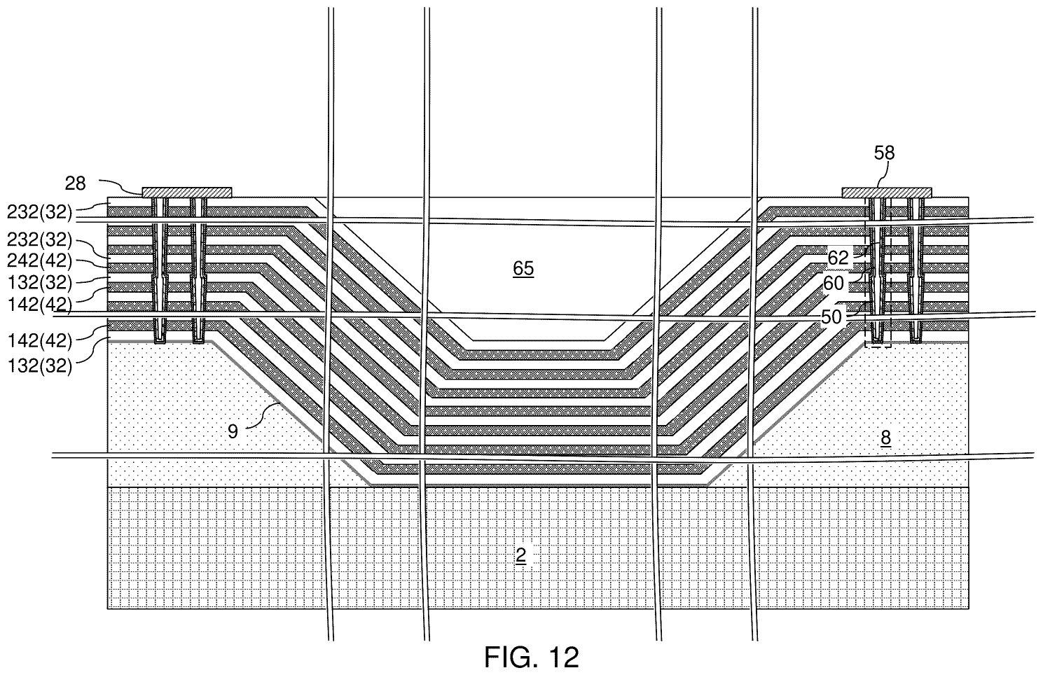

Referring to FIG. 12, a doped semiconductor material having a doping of a second conductivity type can be deposited directly on the physically exposed annular top surfaces of the vertical semiconductor channels 60, and can be patterned (for example, by a combination of lithographic patterning step and an etch process) to form source layers 28. The second conductivity type is the opposite of the first conductivity type. For example, if the first conductivity type is p-type, the second conductivity type is n-type, and vice versa. The dopant concentration of the dopants of the second conductivity type in the source layers 28 can be in a range from 5.0×10¹⁸/cm³ to 2.0×10²¹/cm³, although lesser and greater dopant concentrations can also be employed. The doped semiconductor material can be, for example, doped polysilicon. The thickness of each source layer may be in a range from 50 nm to 300 nm, although lesser and greater thicknesses may also be employed.

The source layer 28 can be formed directly on top surfaces of the memory opening fill structures 58, and specifically, directly on the annular top surfaces of the vertical semiconductor channels 60. The source layer 28 may be patterned by photolithography and etching to remain over the regions of the device containing the memory opening fill structures 58.

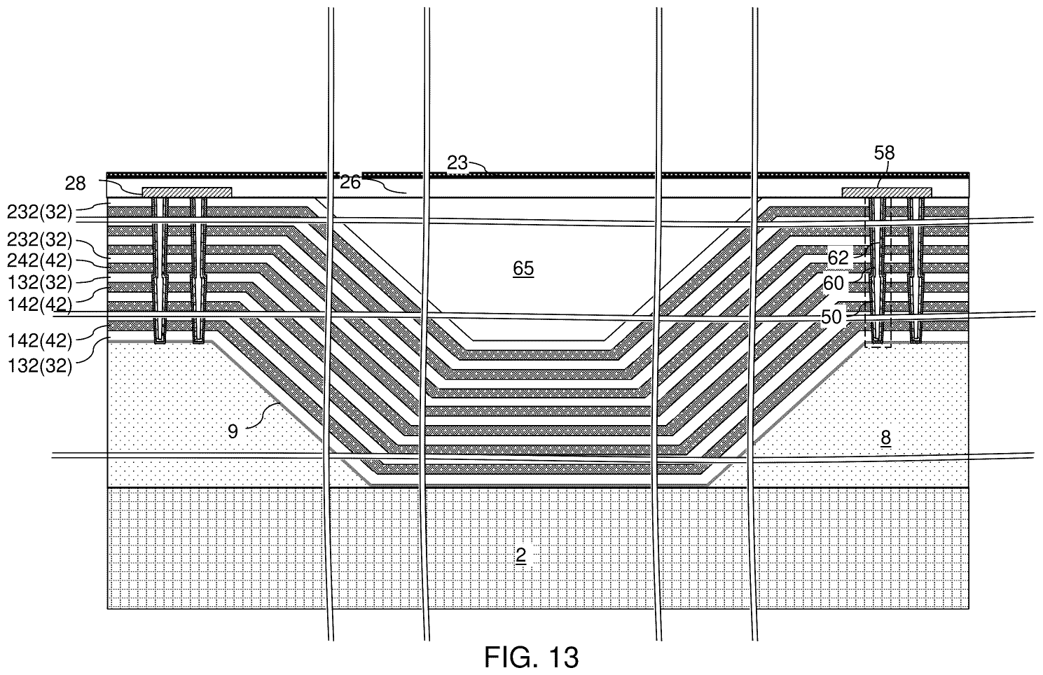

Referring to FIG. 13, a backside dielectric layer 26 can be formed over the alternating stacks (32, 42). The backside dielectric layer 26 comprises a dielectric material such as silicon oxide, and has a thickness in a range from 50 nm to 600 nm, such as from 100 nm to 300 nm, although lesser and greater thicknesses may also be employed. Optionally, a planarization process (such as a chemical mechanical polishing process) may be performed to planarize the top surface of the backside dielectric layer 26.

An optional sacrificial cover layer 23, which may function as a protective cover layer, may be optionally formed over the backside dielectric layer 26. The sacrificial cover layer 23 may comprise titanium nitride, silicon nitride or a dielectric metal oxide, and may have a thickness in a range from 10 nm to 200 nm, although lesser and greater thicknesses may also be employed.

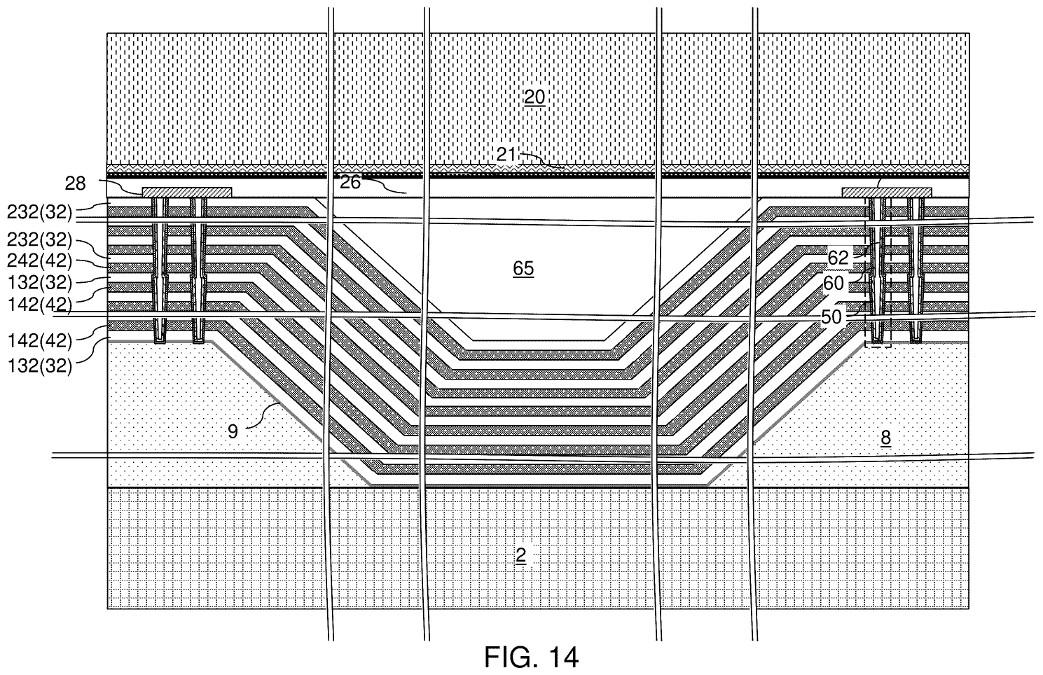

Referring to FIG. 14, a handle substrate 20 can be attached to the backside dielectric layer 26 or to the sacrificial cover layer 23. The handle substrate 20 may comprise a semiconductor material, an insulating material, a conductive material, or a stack thereof, and has a sufficient thickness and mechanical strength to support the alternating stacks (32, 42) during subsequent processing steps. For example, the handle substrate 20 may have a thickness in a range from 300 microns to 1.2 mm. An optional adhesive layer 21 may be employed to facilitate attachment of the handle substrate 20 to the backside dielectric layer 26 or to the sacrificial cover layer 23. The adhesive layer 21 may comprise a silicon oxide layer or a thermally-decomposable adhesive material as known in the art. Alternatively, if the handle substrate 20 comprises an optically transparent material, the adhesive layer 21 may comprise a light-to-heat-conversion (LTHC) release coating material as known in the art, which decomposes upon irradiation with ultraviolet radiation.

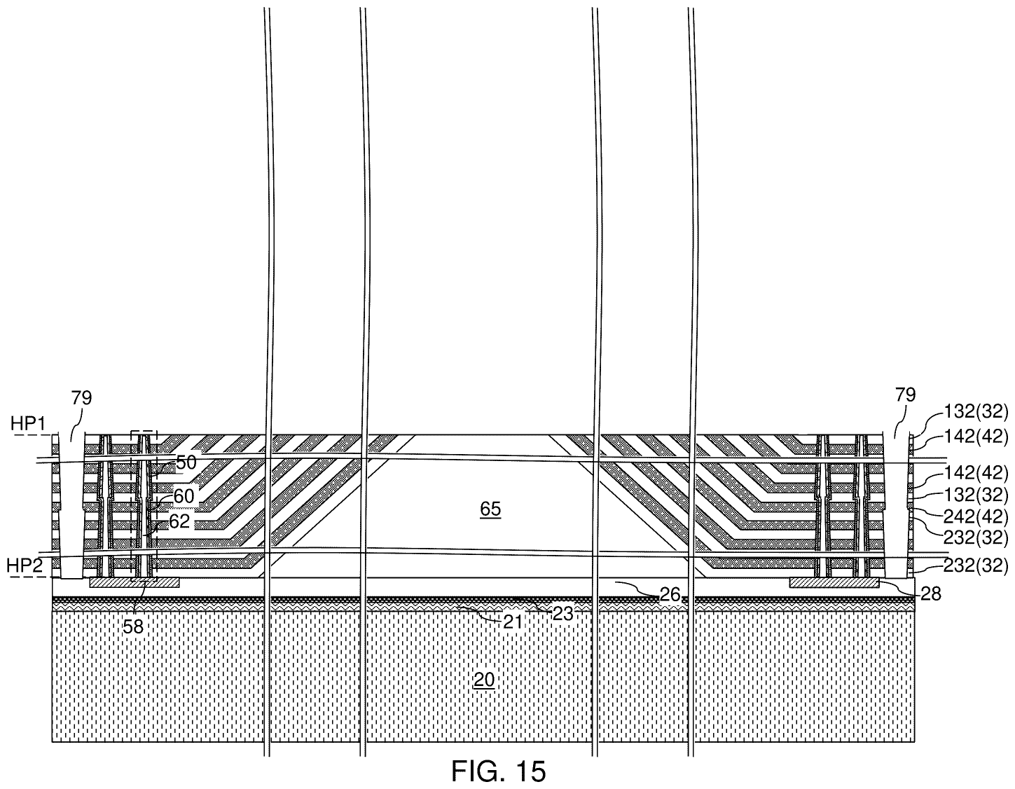

Referring to FIG. 15, the carrier substrate 2 can be detached from the assembly of the handle substrate 20, the matrix layer 8, the alternating stacks (32, 42), and the dielectric mesa structure 65. The carrier substrate 2 may be detached from the assembly by cleaving, grinding, polishing, an anisotropic etch process, an isotropic etch process, or a combination thereof. At least one planarization process can be performed to remove the matrix layer 8 and the portions of the alternating stacks (32, 42) that are more distal from the handle substrate 20 than the horizontal plane including most distal surfaces of the memory opening fill structures 58 from the handle substrate 20. The at least one planarization process may comprise a chemical mechanical polishing process and/or at least one etch process that etches the material(s) of the alternating stacks (32, 42) and/or the material of the matrix layer 8. In one embodiment, a combination of isotropic etch processes (such as wet etch processes) and a chemical mechanical polishing process to remove the matrix layer 8 and portions of the alternating stacks (32, 42) that are embedded in the matrix layer 8. The exemplary structure may be flipped upside down prior to, during or after the planarization process.

A photoresist layer (not shown) can be applied over the in-process alternating stack (32, 42), and can be lithographically patterned to form elongated openings that are parallel to the first horizontal direction. An anisotropic etch process can be performed to transfer the pattern of the openings in the photoresist layer through the in-process alternating stack (32, 42). Lateral isolation trenches 79 laterally extending along the first horizontal direction (which can be a word line direction) can be formed through the in-process alternating stack (32, 42). Each of the lateral isolation trenches 79 may comprise a respective pair of lengthwise sidewalls that are parallel to the first horizontal direction. The width of each lateral isolation trench 79 may be in a range from 150 nm to 1,000 nm, such as from 300 nm to 600 nm, although lesser and greater widths may also be employed. The photoresist layer can be subsequently removed, for example, by ashing.

It is understood that elements in FIG. 15 are illustrated schematically, and the vertical cross-sectional views of the lateral isolation trenches 79 are along a horizontal plane that is perpendicular to the first horizontal direction. In some embodiments, first-tier lateral isolation trenches (not shown) may be formed through the first alternating stack (132, 142) during, prior to or after formation of the first-tier memory openings 149 (e.g., during the processing steps described with reference to FIG. 4), first-tier sacrificial lateral isolation trench fill structures (not shown) may be formed in the first-tier lateral isolation trenches concurrently with, prior to or after formation of the first-tier sacrificial memory opening fill structures 147 (e.g., during the processing steps described with reference to FIG. 5), second-tier lateral isolation trenches may be formed at the processing steps of FIG. 12, and the lateral isolation trenches 79 may be formed by removing the first-tier sacrificial lateral isolation trench fill structures from underneath the second-tier lateral isolation trenches. In this case, the lateral isolation trenches 79 may comprise multiple sets of tapered sidewalls that define multiple regions having variable widths that increase with a vertical distance from a horizontal plane including the top surface of the handle substrate 20. Generally, each of the lateral isolation trenches 79 comprises at least one tapered region having a variable lateral extent that increases along an upward vertical direction when the exemplary structure is oriented as illustrated in FIG. 15.

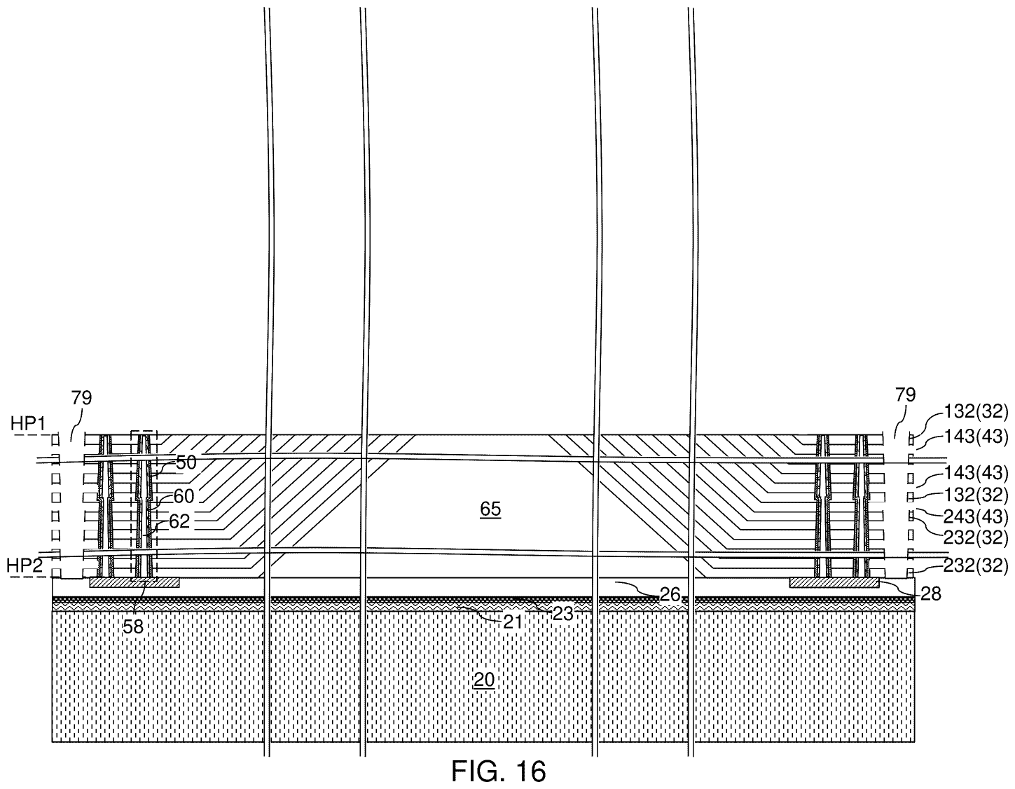

Referring to FIG. 16, an isotropic etch process can be performed to remove the sacrificial material layers (142, 242) selective to the insulating layers (132, 232), the backside dielectric layer 26, and the memory opening fill structures 58. In an illustrative example, the insulating layers (132, 232) may comprise silicon oxide, the sacrificial material layers (142, 242) may comprise silicon nitride. In this case, the isotropic etch process that removes the sacrificial material layers (142, 242) may comprise a wet etch process employing hot phosphoric acid. Laterally-extending cavities 43 can be formed in volumes from which the sacrificial material layers (142, 242) are removed. The laterally-extending cavities 43 may comprise first laterally-extending cavities 143 that are formed in volumes from which the first sacrificial material layers 142 are removed, and second laterally-extending cavities 243 that are formed in volumes from which the second sacrificial material layers 242 are removed. Sidewall surface segments of the memory opening fill structures 58 can be physically exposed to the laterally-extending cavities 43.

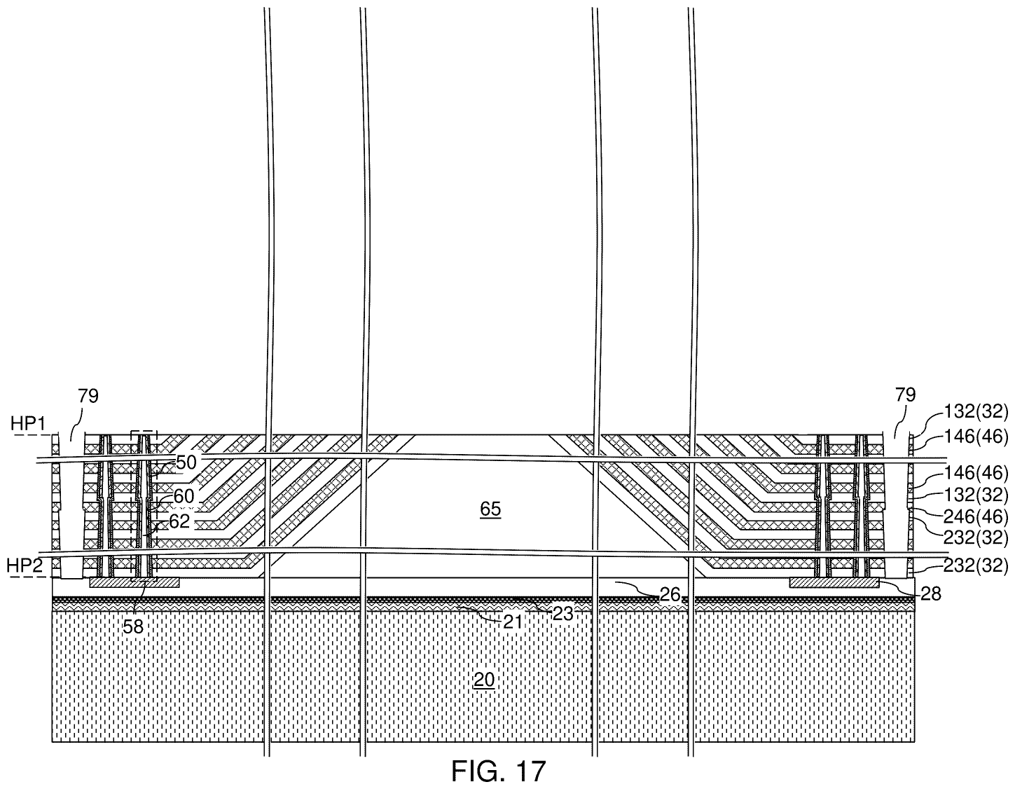

Referring to FIG. 17, an outer blocking dielectric layer (not illustrated), such as an aluminum oxide layer, can be optionally formed in the laterally-extending cavities 43 by a conformal deposition process. At least one electrically conductive material can be conformally deposited in the laterally-extending cavities 43. For example, a metallic barrier material can be conformally deposited in the laterally-extending cavities 43 to form a metallic barrier layer (not expressly shown). The metallic barrier material may comprise, for example, TiN, TaN, WN, MON, TiC, TaC, WC, or a combination thereof. Subsequently, a metal fill material can be conformally deposited in unfilled volumes of the laterally-extending cavities 43 to form metallic fill material portions (not expressly shown). The metal fill material may comprise, for example, Ti, Ta, Mo, Co, Ru, W, Cu, other transition metals, and/or alloys or layer stacks thereof.

Excess portions of the metallic barrier material and the metal fill material that are deposited in the lateral isolation trenches 79 or above the topmost insulating layer 32 can be removed by performing an etch-back process, which may comprise an isotropic etch process and/or an anisotropic etch process. Each contiguous combination of remaining portions of the metallic barrier material and the metal fill material filling a respective one of the laterally-extending cavities 43 constitutes an electrically conductive layer 46. The electrically conductive layers 46 may comprise first electrically conductive layers 146 that replace respective portions of the first sacrificial material layers 142, and second electrically conductive layers 246 that replace respective portions of the second sacrificial material layers 242. An alternating stack of insulating layers 32 and electrically conductive layers 46 can be formed between each neighboring pair of lateral isolation trenches 79 over the handle substrate 20. A plurality of memory blocks comprising respective alternating stacks of insulating layers 32 and electrically conductive layers 46 can be laterally spaced apart from each other by the lateral isolation trenches 79.

In summary, the sacrificial material layers 42 are replaced with the electrically conductive layers 46 to form an alternating stack of insulating layers 32 and electrically conductive layers 46. Slanted sidewalls of the dielectric mesa structure 65 contact a bottom surface of a respective slanted portion of a bottommost insulating layer 32 within the alternating stack (32, 46).

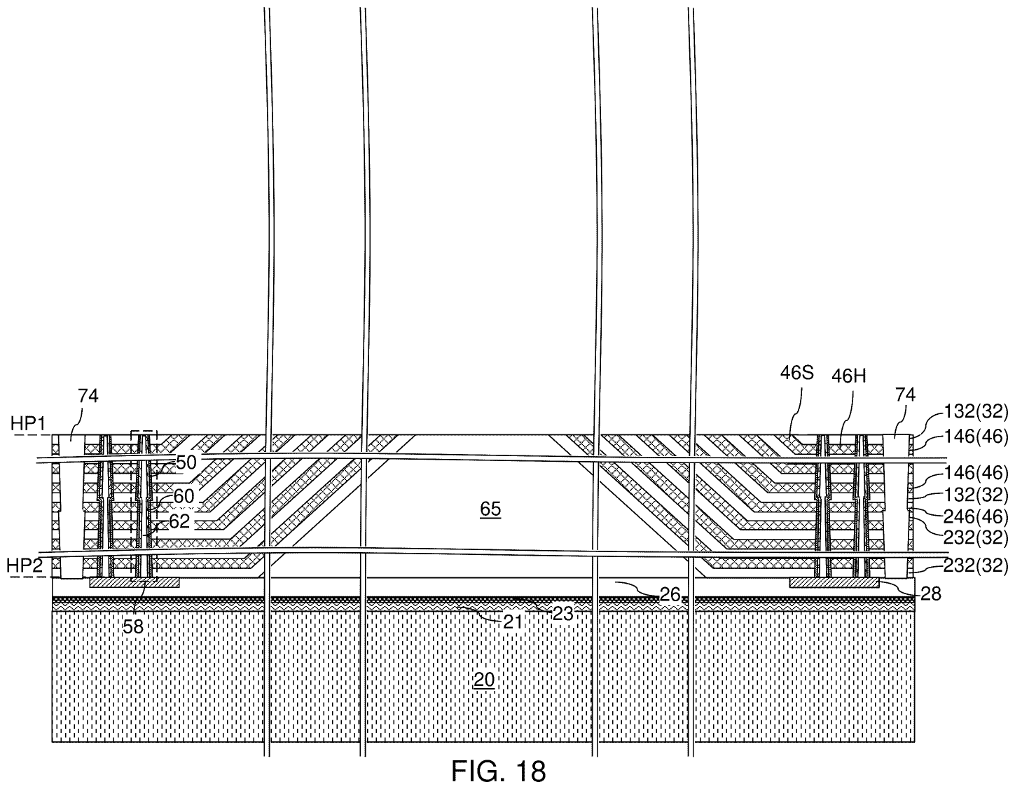

Referring to FIG. 18, an insulating material, such as silicon oxide, can be conformally deposited in each lateral isolation trench 79. The insulating material is them planarized with the top surface of the alternating stack (32, 46) to form a lateral isolation trench fill structure 74 in each lateral isolation trench 79. A lateral isolation trench fill structure 74 can be formed in each lateral isolation trench 79. Each lateral isolation trench fill structure 74 may comprise a sidewall that contacts each of the insulating layers 32 and the electrically conductive layers 46 in an alternating stack (32, 46). Each lateral isolation trench fill structure 74 comprises at least one tapered region having a variable lateral extent that increases along an upward vertical direction when the exemplary structure is positioned with the handle substrate underneath the alternating stack (32, 46).

Each remaining portion of the electrically conductive layers 46 in each alternating stack (32, 46) comprises a respective horizontally-extending portion 46H and a respective slanted portion 46S that extends at a non-zero and a non-orthogonal angle relative to the respective horizontally-extending portion 46H. In other words, the respective slanted portion 46S extends a non-zero and a non-orthogonal angle with respect to a vertical direction in a vertical cross-sectional view. In one embodiment, each of the slanted portions has a respective horizontal end surface located within a first horizontal plane HP1 as illustrated in FIG. 18.

The memory openings 49 vertically extend through the alternating stack (32, 46). The memory opening fill structures 58 are located in the memory openings 49. Each of the memory opening fill structures 58 comprises a respective vertical stack of memory elements (e.g., portions of the memory film 50) located at levels of the electrically conductive layers 46 and a vertical semiconductor channel 60. In a view in which the alternating stacks (32, 46) overlie the handle substrate 20 (such as the view of FIG. 18), each slanted sidewall of the alternating stacks (32, 46) vertically extends from the first horizontal plane HP1 including the topmost surface of the alternating stack (32, 46) to a second horizontal plane HP2 including a bottommost surface of the alternating stack (32, 46). In a view in which the alternating stacks (32, 46) overlie the handle substrate 20 (such as the view of FIG. 18), the slanted portions 46S of the electrically conductive layers 46 in each alternating stack (32, 46) slant upward with an increase in a lateral distance from the memory opening fill structures 58 that are embedded within a respective alternating stack (32, 46).

The memory opening fill structures 58 embedded within an alternating stack (32, 46) contact a top surface of a source layer 28 that underlies the alternating stack (32, 46). The dielectric mesa structure 65 comprises a planar top surface located within the first horizontal plane HP1. In one embodiment, each of the memory opening fill structures 58 comprises a horizontal top surface located within the first horizontal plane HP1, and a horizontal bottom surface located within a second horizontal plane HP2 including a bottom surface of a bottommost insulating layer 32 among the insulating layers 32 in the alternating stack (32, 42).

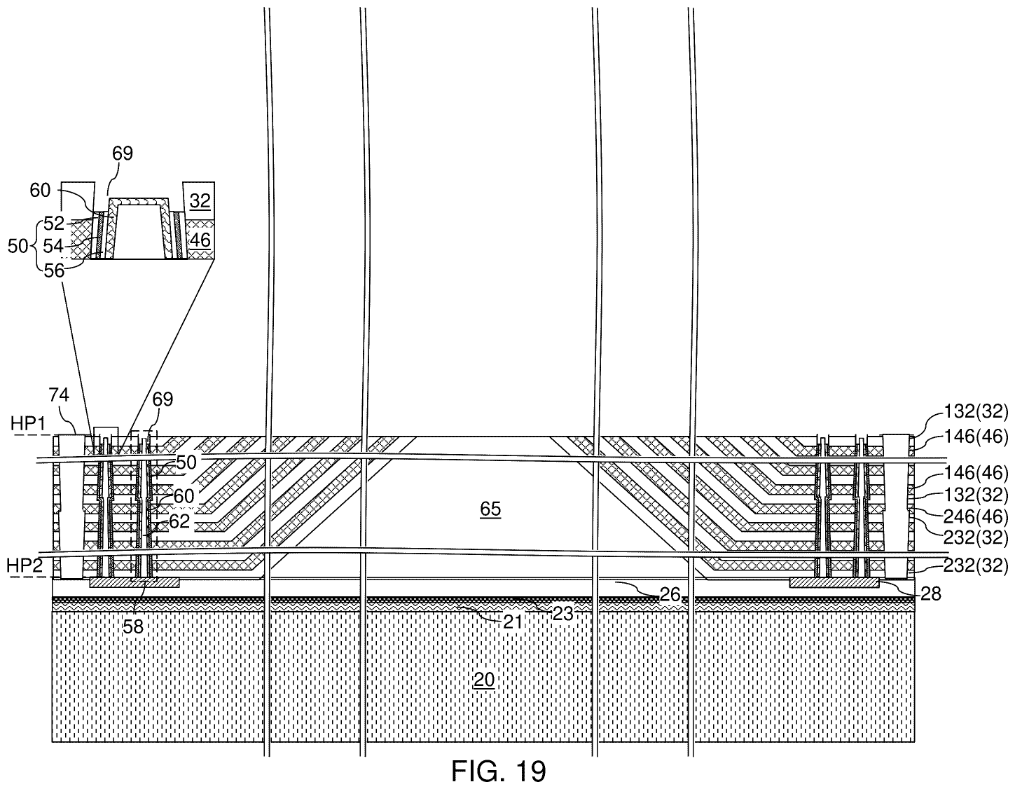

Referring to FIG. 19, at least one selective isotropic etch process can be performed to sequentially etch the materials of the blocking dielectric layers 52, the memory material layers 54, and the optional dielectric liners 56. A recess cavity 69 is formed within each memory opening 49. Surfaces of a vertical semiconductor channel 60 (such as a top surface and a sidewall of the vertical semiconductor channel 60) can be exposed underneath each recess cavity 69.

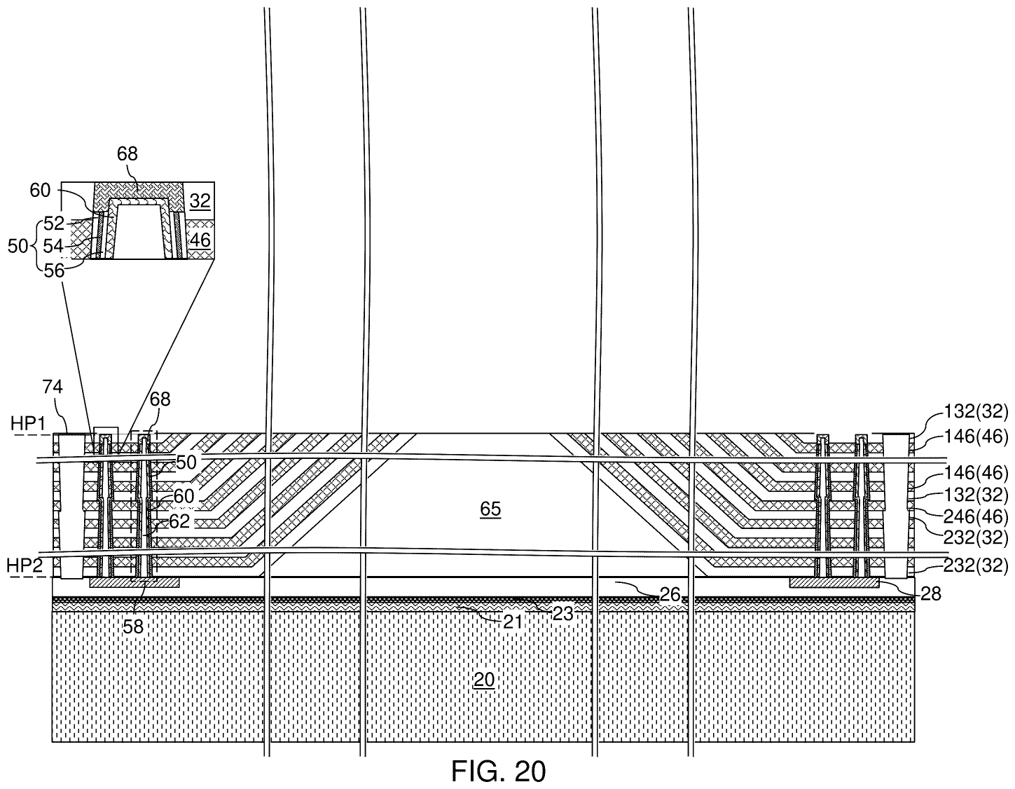

Referring to FIG. 20, a drain region 68 is formed on the end of the vertical semiconductor channel 60 exposed in the recess cavity 69. In one embodiment, the drain region 68 is formed by implanting ions of a second conductivity type into the end of the vertical semiconductor channel 60 exposed in the recess cavity 69. In another embodiment, a semiconductor material (e.g., polysilicon or amorphous silicon) can be deposited within the recess cavity 69. The semiconductor material may be doped in-situ during deposition and/or by ion implantation with dopants of the second conductivity type. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon. Excess portions of the deposited semiconductor material having a doping of the second conductivity type can be removed from above the first horizontal plane HP1 by a planarization process, which may employ a recess etch process or a chemical mechanical polishing process. Each remaining portion of the doped semiconductor material having a doping of the second conductivity type constitutes a drain region 68. Each memory opening fill structure 58 comprises a respective drain region 68 that contacts a top portion of a respective vertical semiconductor channel 60. In one embodiment, each of the memory opening fill structures 58 comprises a vertical semiconductor channel 60 having a doping of a first conductivity type and having an annular bottom surface that contacts a top surface of a source layer 28, and a drain region 68 having a doping of a second conductivity type that is an opposite of the first conductivity type and having a top surface located within the first horizontal plane HP1.

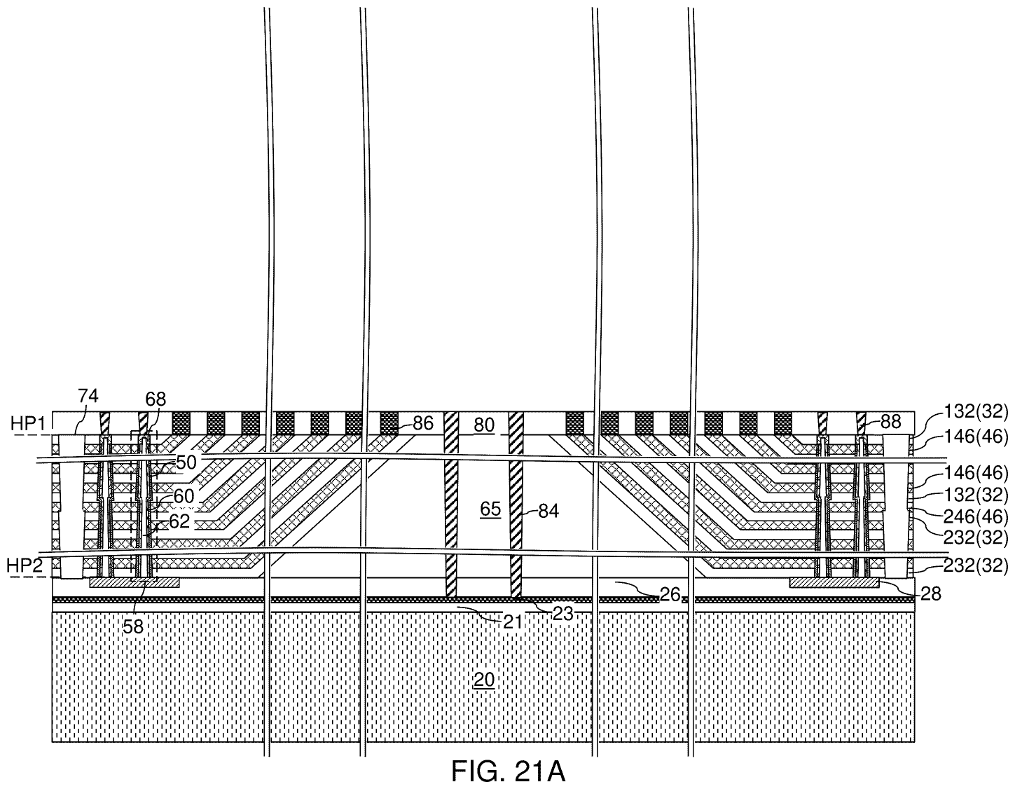

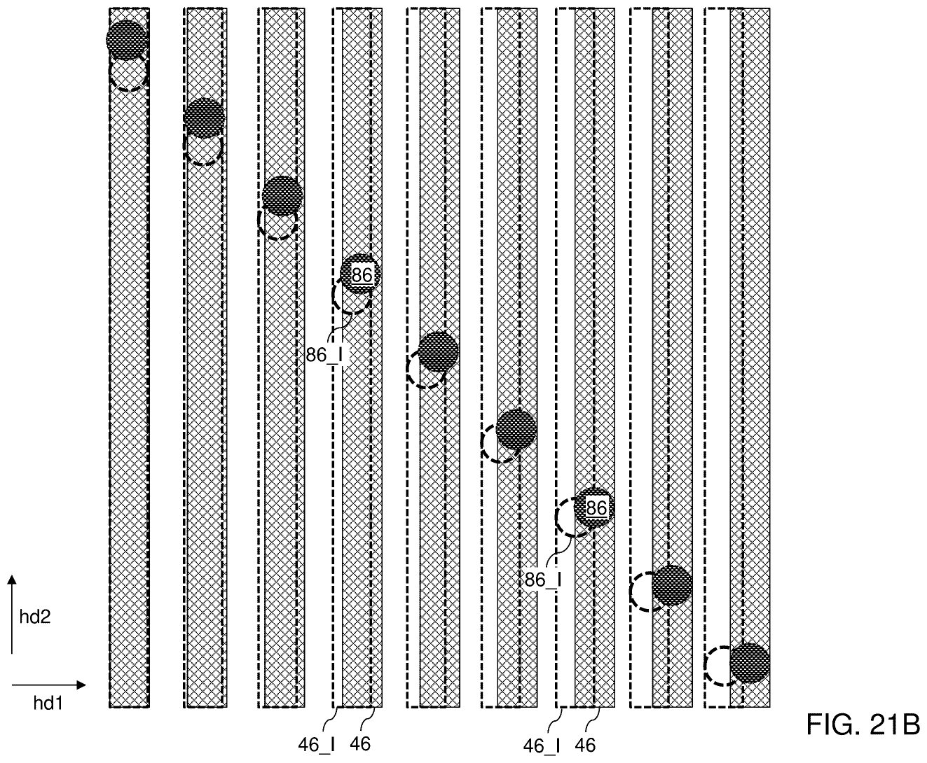

Referring to FIGS. 21A and 21B, a dielectric material, such as undoped silicate glass (i.e., silicon oxide) or a doped silicate glass, can be deposited over the alternating stack (32, 46) to form a contact-level dielectric layer 80. The thickness of the contact-level dielectric layer 80 may be in a range from 100 nm to 600 nm, such as from 200 nm to 400 nm, although lesser and greater thicknesses may also be employed.

An array of openings can be formed over the memory opening fill structures 58, for example, by applying and lithographically patterning a first photoresist layer (not shown), which may be a deep ultraviolet photoresist layer, to form openings within the areas of the memory opening fill structures 58, and by transferring the pattern of the openings in the photoresist layer through the contact-level dielectric layer 80 employing an anisotropic etch process. Drain contact via cavities are formed through the contact-level dielectric layer 80 over physically exposed top surfaces of the drain regions 68. In one embodiment, connection via cavities (i.e., word line connection via cavities) are formed through the contact-level dielectric layer 80 over physically exposed top surfaces of the slanted portions 46S of the electrically conductive layers 46 during the same photolithography and etching steps as the drain contact via cavities. The first photoresist layer can be subsequently removed, for example, by ashing.

In another embodiment, the connection via cavities are formed during photolithography and etching steps from the drain contact via cavities. In this embodiment, a second photoresist layer (not shown) may be applied over the alternating stacks (32, 46), and can be lithographically patterned to form openings in the contact areas, which are areas in which the slanted portions 46S of the electrically conductive layers 46 have top surfaces within the first horizontal plane HP1. The pattern of the planar surfaces of the electrically conductive layers 46 within the first horizontal plane HP1 laterally extend along a second horizontal direction hd2 that is perpendicular to the first horizontal direction hd1. Thus, overlay of a pattern of openings for formation of layer contact via structures for the electrically conductive layers 46 along the second horizontal direction hd2 without significant variability. However, the large vertical and lateral dimensions over which the tapered sidewalls of the dielectric mesa structure 65 extend may result in variability in the lateral dimension of each contact area along the first horizontal direction hd1. Thus, the lateral dimension of the pattern of the electrically conductive layers 46 within the first horizontal plane HP1 may have a scaling variability, i.e., may be formed in a size that is greater than the target size or may be formed in a size that is less than the target size.

According to an aspect of the present disclosure, the variability in the size of the pattern of the electrically conductive layers 46 within the first horizontal plane HP1 may be accommodated by scaling the size of lithographic images for the openings to be formed in the contact areas. In this case, lithographic patterns in different contact areas may be separately exposed using a stitching exposure method so that different overlay corrections and potentially different image scaling may be employed for each contact region.

In an illustrative example, FIG. 21B illustrates ideal locations 46_I for electrically conductive layers 46 and ideal locations 86_I for forming layer contact via structures that contact a respective one of the electrically conductive layers 46. Such ideal locations (46_I, 86_I) are illustrated in dotted lines. Actual locations of the electrically conductive layers 46 and actual locations for forming layer contact via structures 86 are illustrated in solid lines. The lithographic masks for patterning layer contact via cavities have openings at locations that correspond to the ideal locations 86_I for forming the layer contact via structures. During the lithographic exposure process, the magnification of the lithographic image on the second photoresist layer can be adjusted so that the pitch of the openings in the lithographic pattern along the first horizontal direction hd1 matches the actual pitch of the electrically conductive layers 46 along the first horizontal direction within the first horizontal plane HP1. Upon development, the second photoresist layer includes openings that are located over a respective one of the electrically conductive layers 46 in the contact region. An anisotropic etch process can be performed after lithographically forming all openings in the second photoresist layer to transfer the pattern of discrete openings in the second photoresist layer through the contact-level dielectric layer 80. Layer contact via cavities are formed over the slanted portion 46S of each of the electrically conductive layers 46 in each alternating stack (32, 46). The layer contact via cavities are formed with a scaling factor, which may or may not be equal to 1. In contrast, the drain contact via cavities are formed without any scaling, i.e., with the design pitch. The second photoresist layer can be subsequently removed.

A third photoresist layer (not shown) can be applied over the exemplary structure, and can be lithographically patterned to form openings over the area in which the dielectric mesa structure 65 contacts the contact-level dielectric layer 80. An anisotropic etch process can be performed to form openings through the contact-level dielectric layer 80 and the dielectric mesa structure 65 within the areas of the openings in the third photoresist layer. Connection via cavities are formed, which are herein referred to as through-mesa connection via cavities. The third photoresist layer can be subsequently removed, for example, by ashing.

At least one electrically conductive material can be deposited in the drain contact via cavities, the layer contact via cavities, and the through-mesa connection via cavities. The at least one electrically conductive material may comprise a metallic barrier material and a metal fill material. Excess portions of the metallic barrier material and the metal fill material may be removed from above the horizontal plane including the top surface of the contact-level dielectric layer 80, for example, by a chemical mechanical polishing process. Each remaining portion of the at least one conductive material filling the drain contact via cavities constitute drain contact via structures 88. Each remaining portion of the at least one conductive material filling the layer contact via cavities constitute layer contact via structures 86. Each remaining portion of the at least one conductive material filling the through-mesa connection via cavities constitutes a through-mesa connection via structure 84.

The layer contact via structures 86 can be formed directly on a respective one of the end surfaces of the slanted portions 46S of the electrically conductive layers 46. In one embodiment, each of the layer contact via structures 86 has a respective end surface that contacts a respective one of the end surfaces of the slanted portions 46S of the electrically conductive layers 46 within the first horizontal plane HP1. In one embodiment, each of the layer contact via structures 86 has a variable lateral extent (such as a variable width) that increases along an upward vertical direction (which may be measured from a bottommost surface of an alternating stack (32, 46). In one embodiment, each of the drain contact via structures 88 contacts a top surface of a respective one of the memory opening fill structures 58 (e.g., contacts the top surface of the drain regions 68) within the first horizontal plane HP1. In one embodiment, each of the drain contact via structures 88 has a variable lateral extent (such as a variable width) that increases along an upward vertical direction (which may be measured from a bottommost surface of an alternating stack (32, 46). In one embodiment, each of the through-mesa connection via structures 84 vertically extends through the dielectric mesa structure 65, and has a variable lateral extent that increases along an upward vertical direction.

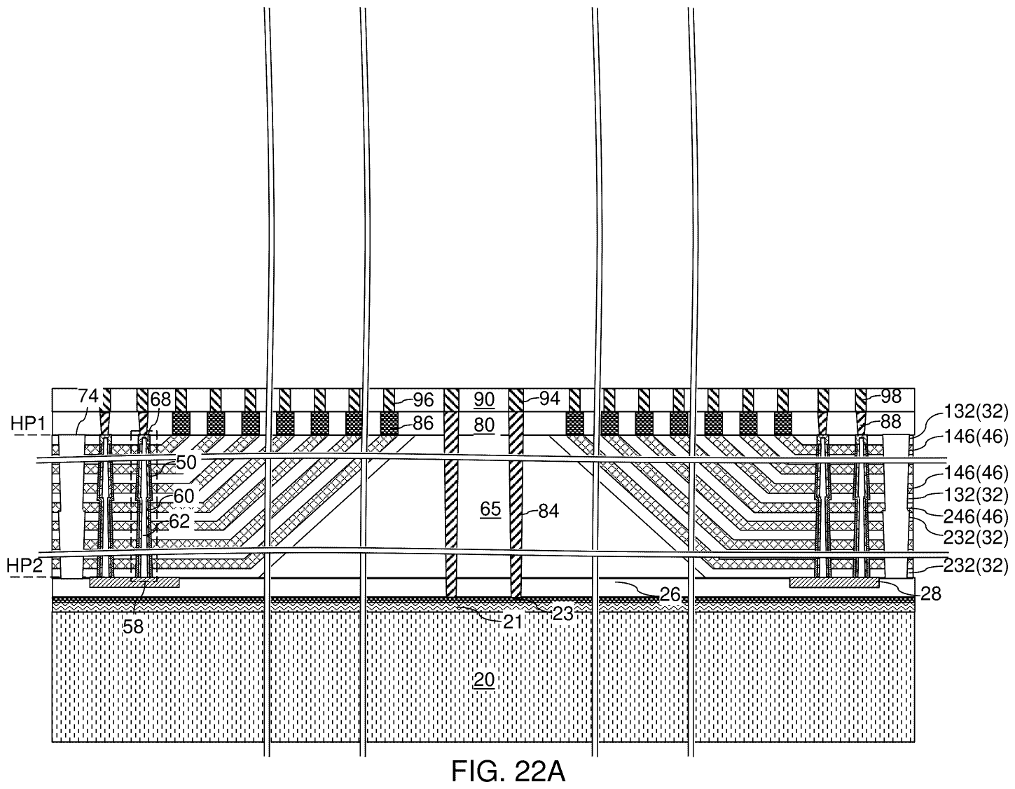

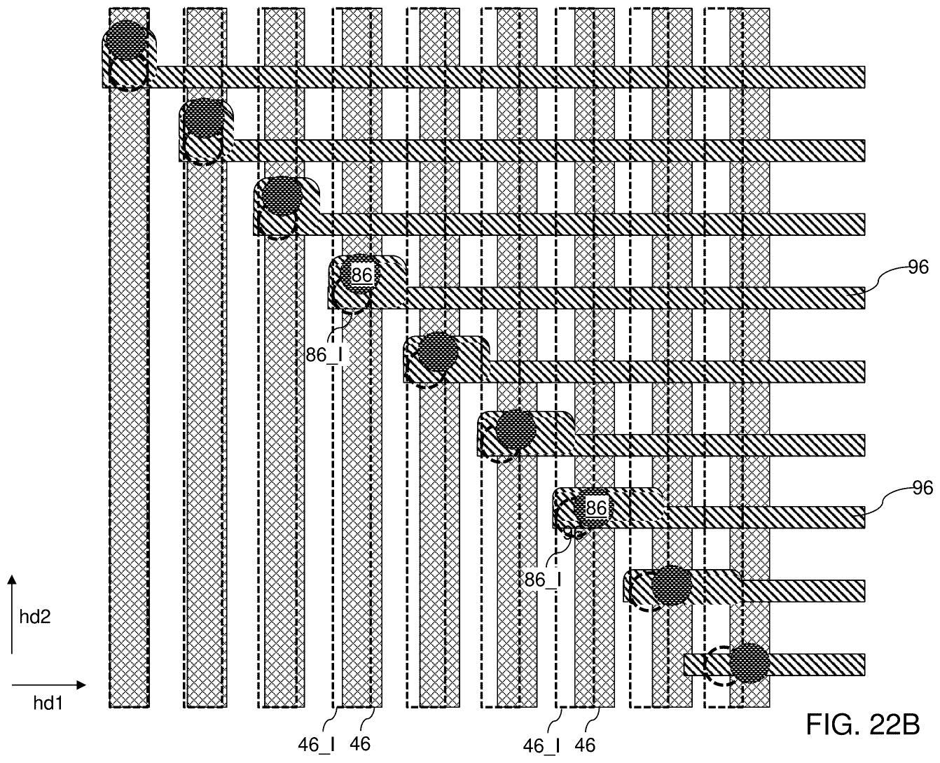

Referring to FIGS. 22A and 22B, a connection-level dielectric layer 90 can be formed above the contact-level dielectric layer 80. Connection via cavities can be formed through the connection-level dielectric layer 90, and can be filled with at least one conductive material (which may comprise at least one conductive material) to form connection-level via structures (98, 96, 94). The connection-level via structures (98, 96, 94) comprise drain connection via structures 98 that contact a respective one of the drain contact via structures 88, layer connection via structures 96 that contact a respective one of the layer contact via structures 86, and over-mesa connection via structures 94 that contacts a respective one of the through-mesa connection via structures 84. Various additional other connection via structures may be formed as needed.

In one embodiment, the pattern of the layer connection via structures 96 may be designed to accommodate the variability of the pattern of the layer contact via structures 86 caused by the variability of the total lateral dimension of the top surfaces of the electrically conductive layers 46 along the first horizontal direction hd1 within the first horizontal plane HP1. In the illustrated example of FIG. 22B, the layer connection via structures 96 provide electrical connection to the layer contact via structures 86 despite the deviations in the locations of the layer contact via structure 86 along the second horizontal direction hd2. The layout illustrated in FIG. 22B is merely an example for accommodating the variability of the size of the pattern of the electrically conductive layers 46 along the first horizontal direction hd1 within the first horizontal plane HP1, and any other alternative design layouts for accommodating the variability of the lateral dimensions of the electrically conductive layers 46 in the first horizontal plane HP1 may be employed.

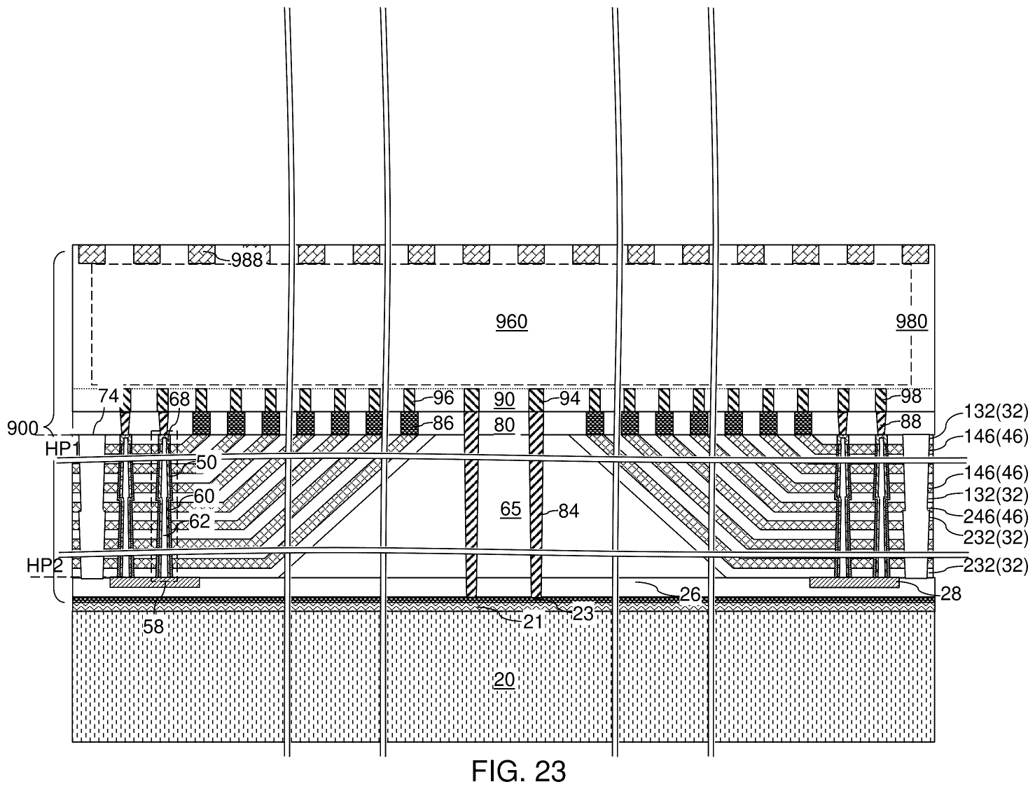

Referring to FIG. 23, additional dielectric material layers and additional metal interconnect structures can be formed over the connection-level dielectric layer 90. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the connection-level dielectric layer 90 are collectively referred to as memory-side metal interconnect structures 980. The metal line structures include bit lines which are electrically connected to the drain connection via structures 98.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including electrically conductive layers 46 and the drain regions 68 in the memory opening fill structures 58. A memory die 900 can thus be provided.

In the memory die 900, the memory-side dielectric material layers 960 are located over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60 via a respective drain region 68; and a two-dimensional array of layer contact via structures 86 electrically connected to a respective one of the electrically conductive layers 46, a subset of which functions as word lines for the three-dimensional memory array. The remaining electrically conductive layers 46 may function as dummy word lines, source side select gate electrodes and drain side select gate electrodes.

In summary, a memory die 900 comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers 32 and electrically conductive layers 46, and further comprises a two-dimensional array of NAND strings (e.g., the memory opening fill structures 58) vertically extending through the alternating stack (32, 46). In one embodiment, at least some of the electrically conductive layers 46 comprise word lines of the two-dimensional array of NAND strings.

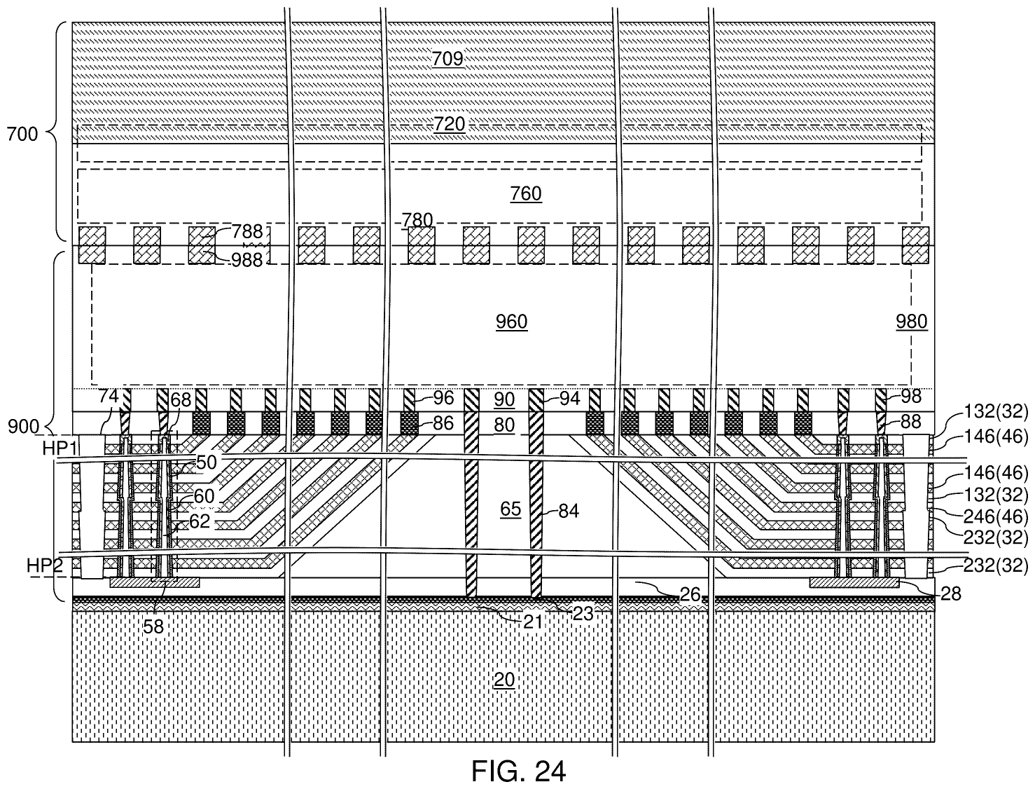

Referring to FIG. 24, a logic die 700 is provided. The logic die 700 comprises a peripheral circuit 720 that is formed on a logic-side substrate 709. The peripheral circuit 720 is configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

A bonded assembly can be formed by bonding a logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

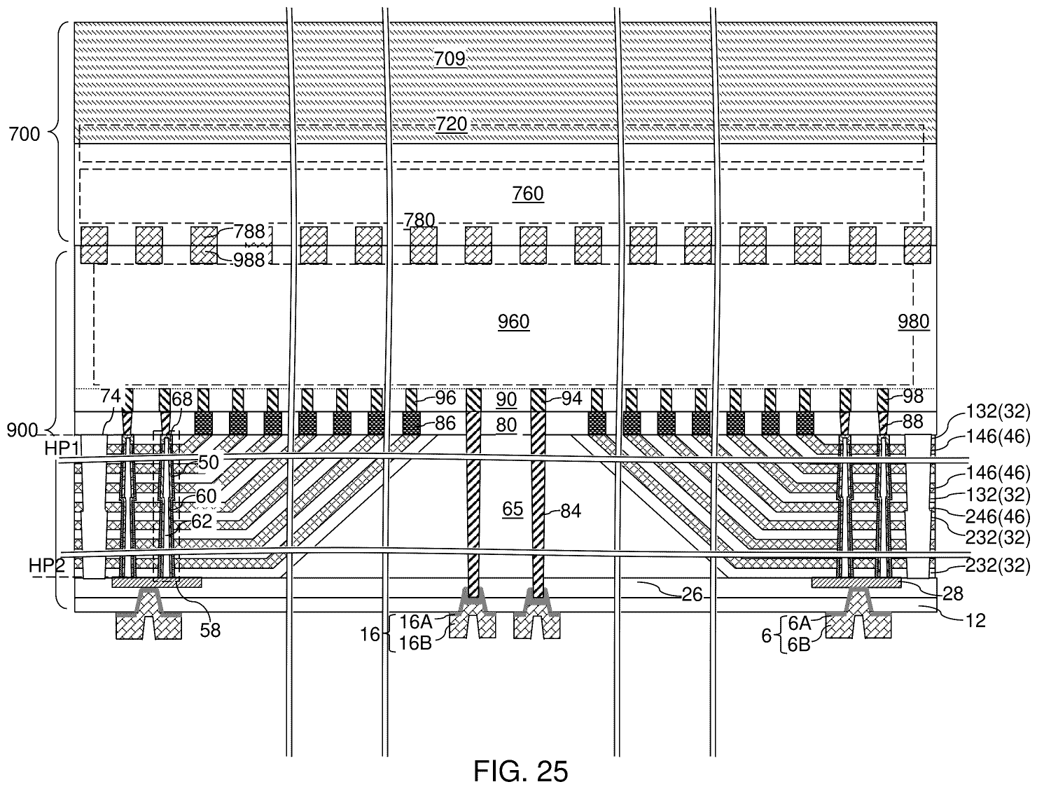

Referring to FIG. 25, the handle substrate 20 can be detached from the bonded assembly including the logic die 700 and the memory die 900 using any suitable method. For example, laser radiation may be used to melt the sacrificial cover layer 23 and/or decompose the adhesive layer 21. Alternatively, selective etching may be used to detach the handle substrate from the bonded assembly. Any portion of the sacrificial cover layer 23, if present after detaching the handle substrate 20, may be removed by selective etching or chemical mechanical polishing.

At least one additional backside dielectric layer 12 may optionally be formed over the backside dielectric layer 26, and backside metal interconnect structures (not illustrated) may be formed in the at least one additional backside dielectric layer 12. The backside metal interconnect structures may comprise backside metal lines and backside metal via structures.

Backside contact pads (6, 16) can be formed in and/or over the at least one additional backside dielectric layer 12. The backside contact pads (6, 16) may comprise source contact metal pads 6 that are electrically connected to one or more of the source layers 28, and connection metal pads 16 that are electrically connected to a respective one of the through-mesa connection via structures 84. Each of the backside contact pads (6, 16) may comprise a respective metallic liner (6A, 16A) and a respective pad metal portion (6B, 16B).

Referring to all drawings and according to various embodiments of the present disclosure, a three-dimensional memory device comprises a memory die 900 comprising an alternating stack (32, 46) of insulating layers 32 and electrically conductive layers 46, wherein each of the electrically conductive layers 46 comprise a respective horizontally-extending portion 46H and a respective slanted portion 46S that extends at a non-zero and non-orthogonal angle relative to the respective horizontally-extending portion 46H, and wherein each of the slanted portions 46S of the electrically conductive layers 46 has a respective horizontal end surface located within a first horizontal plane HP1; memory openings 49 vertically extending through the alternating stack (32, 46); memory opening fill structures 58 located in the memory openings 49 and comprising a respective vertical semiconductor channel 60 and a respective vertical stack of memory elements located at levels of the electrically conductive layers 46; and layer contact via structures 86 having a respective end surface that contacts a respective one of the end surfaces of the slanted portions 46S of the electrically conductive layers 46 within the first horizontal plane HP1. The memory device also comprises a logic die 700 comprising a peripheral circuit 720, wherein the logic die 700 is bonded to the memory die 900.

In one embodiment, the three-dimensional memory device comprises a dielectric mesa structure 65 having a slanted sidewall that contacts a bottom surface of a slanted portion of a bottommost insulating layer 32 within the alternating stack (32, 46). In one embodiment, the slanted sidewall vertically extends from the first horizontal plane HP1 to a second horizontal plane HP2 including a bottommost surface of the alternating stack (32, 46). In one embodiment, the dielectric mesa structure 65 comprises a planar top surface located within the first horizontal plane HP1.

In one embodiment, the three-dimensional memory device further comprises: a through-mesa connection via structure 84 vertically extending through the dielectric mesa structure 65 and having a variable lateral extent that increases along an upward vertical direction; at least one backside dielectric layer 12 underlying the alternating stack (32, 46) and the dielectric mesa structure 65; and a backside contact pad 16 embedded in the at least one backside dielectric layer 12 and electrically connected to the through-mesa connection via structure 84.

In one embodiment, the slanted portions 46S of the electrically conductive layers 46 slant upward with an increase in a lateral distance from the memory opening fill structures 58; and the memory opening fill structures 58 contact a top surface of a source layer 28 that underlies the alternating stack (32, 46). In one embodiment, the vertical semiconductor channels 60 contact the source layer 28. In one embodiment, the vertical semiconductor channel 60 has a doping of a first conductivity type; and the source layer 28 comprises a semiconductor material having a doping of a second conductivity type that is an opposite of the first conductivity type.

In one embodiment, each of the memory opening fill structures 58 comprises at least one tapered region having a variable lateral extent that decreases along an upward vertical direction. In one embodiment, each of the memory opening fill structures 58 comprises a horizontal top surface located within the first horizontal plane HP1, and a horizontal bottom surface located within a second horizontal plane HP2 including a bottom surface of a bottommost insulating layer 32 among the insulating layers 32 in the alternating stack (32, 46). In one embodiment, each of the memory opening fill structures 58 also comprises a drain region 68 having a doping of a second conductivity type that is an opposite of the first conductivity type and having a top surface located within the first horizontal plane HP1.

In one embodiment, the three-dimensional memory device comprises a lateral isolation trench fill structure 74 having a sidewall that contacts each of the insulating layers 32 and the electrically conductive layers 46 in the alternating stack (32, 46), wherein the lateral isolation trench fill structure 74 comprises at least one tapered region having a variable lateral extent that increases along an upward vertical direction. In one embodiment, the three-dimensional memory device comprises drain contact via structures 88 contacting a top surface of a respective one of the memory opening fill structures 58 within the first horizontal plane HP1.

In one embodiment, the non-zero and non-orthogonal angle is greater than 0.5 degrees and less than 60 degrees.

In one embodiment, the memory die 900 further comprises memory-side bonding pads 988 embedded within the memory-side dielectric material layers 960; and the logic die 700 further comprises logic-side bonding pads 788 embedded within logic-side dielectric material layers 760 and bonded to the memory-side bonding pads 988.

The various embodiments of the present disclosure can be employed to provide a three-dimensional memory device that omits high cost steps of forming stepped surfaces in the alternating stack and/or insulating spacers that laterally surround layer contact via structures 86. Electrically conductive layers 46 (e.g., word lines and select gate electrodes) can be formed with slanted portions 46S that extend at a non-zero and non-orthogonal angle with respective to a horizontal plane. The slanted portions 46S provide planar surfaces within a first horizontal plane HP1, at which electrical contact is made between the electrically conductive layers 46 and layer contact via structures 86. Thus, all contact areas between the electrically conductive layers 46 and the layer contact via structures 86 can be formed within a single horizontal plane, i.e., the first horizontal plane HP1. The methods and structures of the embodiments of the present disclosure provide a simpler, lower-cost manufacturing process for a three-dimensional memory device.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device comprising:
a memory die comprising:
an alternating stack of insulating layers and electrically conductive layers, wherein each of the electrically conductive layers comprise a respective horizontally-extending portion and a respective slanted portion that extends at a non-zero and non-orthogonal angle relative to the respective horizontally-extending portion, and wherein each of the slanted portions of the electrically conductive layers has a respective horizontal end surface located within a first horizontal plane;
memory openings vertically extending through the alternating stack;
memory opening fill structures located in the memory openings and comprising a respective vertical semiconductor channel and a respective vertical stack of memory elements located at levels of the electrically conductive layers; and
layer contact via structures having a respective end surface that contacts a respective one of the end surfaces of the slanted portions of the electrically conductive layers within the first horizontal plane; and
a logic die comprising a peripheral circuit, wherein the logic die is bonded to the memory die.

2. The three-dimensional memory device of claim 1, further comprising a dielectric mesa structure having a slanted sidewall that contacts a bottom surface of a slanted portion of a bottommost insulating layer within the alternating stack.

3. The three-dimensional memory device of claim 2, wherein the slanted sidewall vertically extends from the first horizontal plane to a second horizontal plane including a bottommost surface of the alternating stack.

4. The three-dimensional memory device of claim 2, wherein the dielectric mesa structure comprises a planar top surface located within the first horizontal plane.

5. The three-dimensional memory device of claim 2, further comprising:
a through-mesa connection via structure vertically extending through the dielectric mesa structure and having a variable lateral extent that increases along an upward vertical direction;
at least one backside dielectric layer underlying the alternating stack and the dielectric mesa structure; and
a backside contact pad embedded in the at least one backside dielectric layer and electrically connected to the through-mesa connection via structure.

6. The three-dimensional memory device of claim 1, wherein:
the slanted portions of the electrically conductive layers slant upward with an increase in a lateral distance from the memory opening fill structures; and
the memory opening fill structures contact a top surface of a source layer that underlies the alternating stack.

7. The three-dimensional memory device of claim 6, wherein each of the vertical semiconductor channels contacts the source layer.

8. The three-dimensional memory device of claim 7, wherein:
the vertical semiconductor channel has a doping of a first conductivity type; and
the source layer comprises a semiconductor material having a doping of a second conductivity type that is an opposite of the first conductivity type.

9. The three-dimensional memory device of claim 1, wherein each of the memory opening fill structures comprises at least one tapered region having a variable lateral extent that decreases along an upward vertical direction.

10. The three-dimensional memory device of claim 7, wherein each of the memory opening fill structures comprises a horizontal top surface located within the first horizontal plane, and a horizontal bottom surface located within a second horizontal plane including a bottom surface of a bottommost insulating layer among the insulating layers in the alternating stack.

11. The three-dimensional memory device of claim 10, wherein each of the memory opening fill structures further comprises a drain region having a doping of a second conductivity type that is an opposite of the first conductivity type and having a top surface located within the first horizontal plane.

12. The three-dimensional memory device of claim 1, further comprising a lateral isolation trench fill structure having a sidewall that contacts each of the insulating layers and the electrically conductive layers in the alternating stack, wherein the lateral isolation trench fill structure comprises at least one tapered region having a variable lateral extent that increases along an upward vertical direction.

13. The three-dimensional memory device of claim 1, further comprising drain contact via structures contacting a top surface of a respective one of the memory opening fill structures within the first horizontal plane.

14. The three-dimensional memory device of claim 1, wherein the non-zero and non-orthogonal angle is greater than 0.5 degrees and less than 60 degrees.

15. The three-dimensional memory device of claim 1, wherein:
the memory die further comprises memory-side bonding pads embedded within the memory-side dielectric material layers; and
the logic die further comprises logic-side bonding pads embedded within logic-side dielectric material layers and bonded to the memory-side bonding pads.

16. A method of forming a device structure, the method comprising:
forming a recess region comprising a tapered sidewall in a matrix layer;
conformally depositing an in-process alternating stack of insulating layers and sacrificial material layers, wherein the in-process alternating stack comprises a horizontally-extending portion overlying a top surface of the matrix layer and a slanted portion overlying the tapered sidewall of the recess region;
forming memory openings through the horizontally-extending portion of the in-process alternating stack;
forming memory opening fill structures in the memory openings, wherein each of the memory opening fill structures comprises a respective vertical semiconductor channel and a respective vertical stack of memory elements;
replacing the sacrificial material layers with electrically conductive layers to form an alternating stack of the insulating layers and the electrically conductive layers;
forming memory-side metal interconnect structures embedded in memory-side dielectric material layers over the alternating stack of the insulating layers and the electrically conductive layers;
forming memory-side bonding pads on or in the memory-side dielectric material layers;
providing a logic die comprising logic-side bonding pads and a peripheral circuit; and
bonding the logic-side bonding pads to the memory-side bonding pads.

17. The method of claim 16, further comprising forming a source layer over the in-process alternating stack before replacing the sacrificial material layers with the electrically conductive layers, wherein the source layer is formed directly on top surfaces of the memory opening fill structures.

18. The method of claim 16, further comprising removing the matrix layer and portions of the in-process alternating stack that overlie a horizontal plane including the top surface of the matrix layer.

19. The method of claim 18, wherein:
each of the electrically conductive layers in the alternating stack comprises a respective horizontally-extending portion and a respective slanted portion that extends at a non-zero and a non-orthogonal angle with respective to a vertical direction in a vertical cross-sectional view; and
each of the slanted portions has a respective horizontal end surface located within a first horizontal plane.

20. The method of claim 19, further comprising forming layer contact via structures directly on a respective one of the end surfaces of the slanted portions.
